(19) United States
(12) Patent Application Publication
(10) Pub. No.: US 2026/0282718 A1
(43) Pub. Date: Sep. 17, 2026

(54) DISPLAY DEVICE AND ELECTRONIC DEVICE INCLUDING THE SAME

(71) Applicant: Samsung Display Co., LTD., Yongin-si (KR)

(72) Inventors: Tae Ho KIM, Yongin-si (KR); Oh Jeong KWON, Yongin-si (KR); Jong Ho SON, Yongin-si (KR); Seung Yeon JEONG, Yongin-si (KR)

(21) Appl. No.: 19/382,494

(22) Filed: Nov. 7, 2025

(30) Foreign Application Priority Data
Mar. 12, 2025 (KR) 10-2025-0032185

(51) Int. Cl. H10K 59/80; G06F 3/041; G06F 3/044; H10K 59/12; H10K 59/131; H10K 59/35; H10K 59/40

(52) U.S. Cl. CPC H10K 59/878; G06F 3/0412; H10K 59/1201; H10K 59/131; H10K 59/353; H10K 59/40; G06F 3/0446

(57) ABSTRACT

A display device includes emission areas including light emitting elements, respectively, an encapsulation layer on the light emitting elements, a reflective polarizing member on the encapsulation layer and including a wire grid pattern which, among incident light from outside the display device, transmits light having an optical axis in a first direction and reflects light having an optical axis in a second direction orthogonal to the first direction, and an absorptive polarizing member which is on the reflective polarizing member and transmits the light having the optical axis in the first direction together with absorbing the light having the optical axis in the second direction.

This application claims priority to Korean Patent Application No. 10-2025-0032185, filed on Mar. 12, 2025, and all the benefits accruing therefrom under 35 U.S.C. § 119, the disclosure of which is incorporated herein in its entirety by reference.

### BACKGROUND

### 1. Field

The present disclosure relates to a display device and an electronic device including the same.

### 2. Description of the Related Art

As the information society develops, demands for display devices for displaying images are increasing in various forms. For example, display devices are applied to various electronic devices such as smartphones, digital cameras, laptop computers, navigation devices, and smart televisions.

The display devices may be flat panel display devices such as liquid crystal display devices, field emission display devices, and light emitting display devices. The light emitting display devices may include an organic light emitting display device including an organic light emitting element, an inorganic light emitting display device including an inorganic light emitting element such as an inorganic semiconductor, and an ultrasmall light emitting display device including an ultrasmall light emitting element.

Since the organic light emitting display device including the organic light emitting element does not need a light source such as a backlight unit, it is low in power consumption, can be made lightweight and thin, and has a wide viewing angle, high luminance and contrast, and fast response speed. Due to these high-quality characteristics, the organic emitting display device is drawing attention as a next-generation display device.

### SUMMARY

The organic light emitting display device may include a polarizing film to prevent a decrease in the visibility of a displayed image due to reflection of external light. However, since a portion of light emitted from the organic light emitting element is blocked by the polarizing film, the ratio of light emitted to the outside to light emitted from the organic light emitting element, that is, the light efficiency of the organic light emitting element may be reduced.

Aspects of the present disclosure provide a display device which can prevent a decrease in the visibility of a displayed image by applying a polarizing member while increasing the light efficiency of a light emitting element.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including a substrate, a plurality of light emitting elements located on the substrate and located in a plurality of emission portions, respectively, an encapsulation layer located on the light emitting elements, a reflective polarizing member located on the encapsulation layer and including a wire grid pattern which transmits light having an optical axis in a first direction among incident light and reflects light having an optical axis in a second direction orthogonal to the first direction and an absorptive polarizing member located on the reflective polarizing member and transmitting light having an optical axis in the first direction while absorbing light having an optical axis in the second direction.

The light emitting elements include a first light emitting element located in a first emission portion among the emission portions and emitting light of a first wavelength band, a second light emitting element located in a second emission portion among the emission portions and emitting light of a second wavelength band and a third light emitting element located in a third emission portion among the emission portions and emitting light of a third wavelength band.

The wire grid pattern may overlap the third emission portion.

The light of the third wavelength band may be light of a blue wavelength band.

The absorptive polarizing member may overlap the first emission portion, the second emission portion, and the third emission portion.

The display device may further include an adhesive layer located between the reflective polarizing member and the absorptive polarizing member.

The adhesive layer may cover the wire grid pattern.

The display device may further include a phase retardation layer which delays a phase of incident light.

The phase retardation layer may include an alignment layer located on the encapsulation layer and a liquid crystal layer including liquid crystals located on the alignment layer.

The display device may further include a connector located on the encapsulation layer and a sensor electrode located on the connector.

The phase retardation layer may be located between the sensor electrode and the reflective polarizing member, and further including a first touch insulating layer located between the sensor electrode and the phase retardation layer.

The phase retardation layer may be located between the connector and the sensor electrode, and further including a first touch insulating layer located between the sensor electrode and the reflective polarizing member.

The display device may further include a first touch insulating layer located between the sensor electrode and the connector, where the phase retardation layer may be located between the first touch insulating layer and the reflective polarizing member.

The encapsulation layer may include a first encapsulating inorganic layer located on the light emitting elements, a phase retardation layer located on the first encapsulating inorganic layer and a second encapsulating inorganic layer located on the phase retardation layer.

According to another aspect of the present disclosure, there is provided a method of manufacturing a display device including forming a plurality of light emitting elements on a substrate in a first emission portion, a second emission portion and a third emission portion, respectively, forming an encapsulation layer on the light emitting elements, and attaching a phase retardation layer onto the encapsulation layer, depositing an etch-stop layer on the phase retardation layer, forming a reflective metal pattern in the third emission portion by depositing a reflective metal on the etch-stop layer and patterning the reflective metal, spraying a first resin onto the reflective metal pattern using an inkjet device, forming a mask pattern on the reflective metal pattern by positioning a mold having a selected protruding pattern on the first resin and pressing the mold using a roller and forming a wire grid pattern by etching the reflective metal pattern according to the mask pattern and removing the mask pattern.

The method may further include depositing a low-reflective material on the wire grid pattern, forming a photoresist pattern, which overlaps the wire grid pattern in a thickness direction of the substrate, on the low-reflective material, forming a low-reflective layer on the wire grid pattern by etching a portion of the low-reflective material which is exposed without being covered by the photoresist pattern and attaching an absorptive polarizing member on the wire grid pattern.

The forming of the mold having the selected protruding pattern may include forming a plurality of depressed patterns in a base substrate, applying a second resin to fill the depressed patterns, placing a base film on the base substrate to which the second resin is applied, forming the selected protruding pattern by irradiating ultraviolet light to cure the second resin on the base film and separating the base substrate from the base film.

According to another aspect of the present disclosure, there is provided an electronic device including a display module displaying an image and
a processor transmitting an image data signal to the display module. The display module includes a substrate, a plurality of light emitting elements located on the substrate and located in a plurality of emission portions, respectively, an encapsulation layer located on the light emitting elements and a reflective polarizing member located on the encapsulation layer and including a wire grid pattern which transmits light having an optical axis in a first direction among incident light and reflects light having an optical axis in a second direction orthogonal to the first direction, where the light emitting elements include a first light emitting element located in a first emission portion among the emission portions and emitting light of a first wavelength band, a second light emitting element located in a second emission portion among the emission portions and emitting light of a second wavelength band and a third light emitting element located in a third emission portion among the emission portions and emitting light of a third wavelength band, and the reflective polarizing member overlaps the third emission portion.

The light of the third wavelength band may be light of a blue wavelength band.

The wire grid pattern may overlap the third emission portion.

According to a display device and an electronic device including the same according to embodiments, it is possible to increase the efficiency of blue and white light by applying a reflective polarizing member to a blue emission area and possible to prevent a decrease in the visibility of a displayed image by maintaining low reflectivity by applying an absorptive polarizing member to the entire surface of a display panel.

However, the effects of the present disclosure are not restricted to the one set forth herein. The above and other effects of the present disclosure will become more apparent to one of daily skill in the art to which the present disclosure pertains by referencing the detailed description of the present disclosure given below.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to an embodiment;

FIG. 2 is a plan view of the display device according to an embodiment;

FIG. 3 is a side view of the display device according to an embodiment;

FIG. 4 is a schematic plan view of a touch sensing unit of FIG. 3 according to an embodiment;

FIG. 5 is an enlarged plan view illustrating a touch node of FIG. 4 according to an embodiment;

FIG. 6 is a cross-sectional view of a display panel taken along line I-I′ of FIG. 5 according to an embodiment;

FIG. 7 is a cross-sectional view of a display panel taken along line I-I′ of FIG. 5 according to an embodiment;

FIG. 8 is a cross-sectional view of a display panel taken along line I-I′ of FIG. 5 according to an embodiment;

FIG. 9 is a cross-sectional view of a display panel taken along line I-I′ of FIG. 5 according to an embodiment;

FIG. 10 is Comparative Example 1 in which a reflective polarizing member is removed from the embodiment of FIG. 6, and a phase retardation layer and an absorptive polarizing member are applied;

FIG. 11 is Comparative Example 2 in which an absorptive polarizing member is removed from the embodiment of FIG. 6, and a phase retardation layer and a reflective polarizing member are applied;

FIG. 12 is a flowchart illustrating a process of manufacturing (or providing) a display device according to an embodiment;

FIGS. 13 through 22 are cross-sectional views illustrating processes of manufacturing (or providing) the display device according to an embodiment;

FIG. 23 is a flowchart illustrating a process of an imprint mold applied to operation S500 of FIG. 12 according to an embodiment;

FIGS. 24 through 27 are cross-sectional views illustrating the process of manufacturing (or providing) the imprint mold;

FIG. 28 is a block diagram of an electronic device according to an embodiment; and

FIG. 29 is a schematic diagram of electronic devices according to various embodiments.

### DETAILED DESCRIPTION

The invention will now be described more fully hereinafter with reference to the accompanying drawings, in which various embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. The same reference numbers indicate the same components throughout the specification. In the attached drawing figures, the thickness of layers and regions is exaggerated for clarity.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will also be understood that when a layer is referred to as being related to another element such as being “on” another layer or substrate, it can be directly on the other layer or substrate, or intervening layers may also be present. In contrast, when an element is referred to as being related to another element such as being “directly on” another element, there are no intervening elements present.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” “At least one of A and B” or “at least one selected from A and B” means “A and/or B.” As used herein, the term “and/or” includes any and all combinations of one or more of the associated listed items. Within the Figures and the text of the disclosure, a reference number indicating a singular form of an element may also be used to reference a plurality of the element.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. A region illustrated or described as flat may, typically, have rough and/or nonlinear features, for example. Moreover, sharp angles that are illustrated may be rounded. Thus, the regions illustrated in the drawing figures are schematic in nature and their shapes are not intended to illustrate the precise shape of a region and are not intended to limit the scope of the present claims.

Hereinafter, embodiments of the invention will be described in detail with reference to the accompanying drawings.

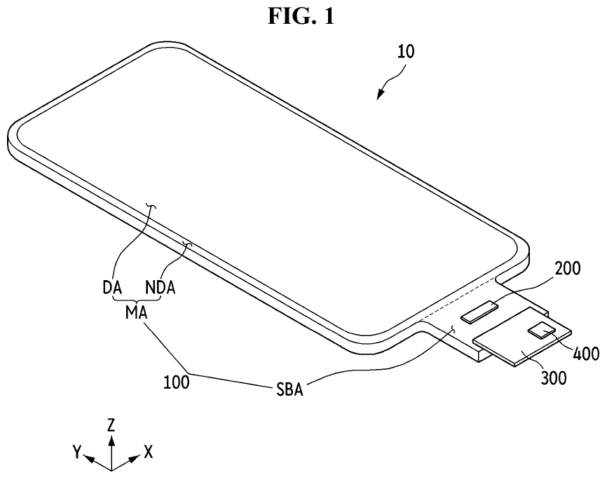

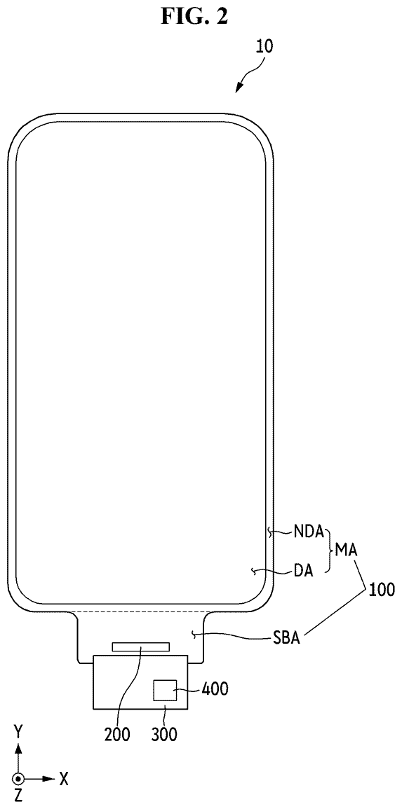

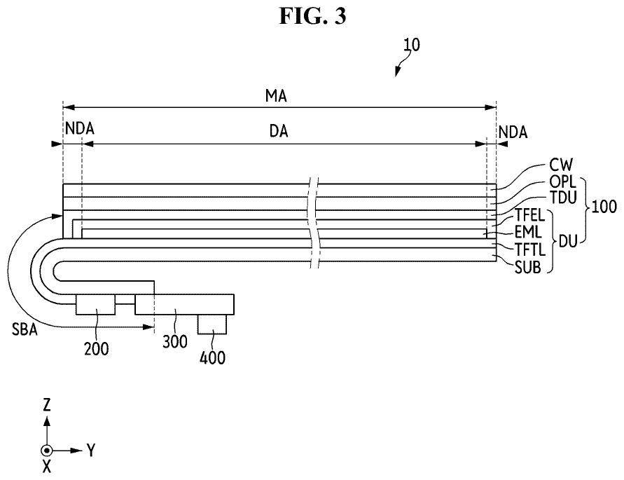

FIG. 1 is a perspective view of a display device 10 according to an embodiment. FIG. 2 is a plan view of the display device 10 according to an embodiment. FIG. 3 is a side view of the display device 10 according to an embodiment.

Referring to FIGS. 1 through 3, the display device 10 according to the embodiment may be applied to portable electronic devices such as mobile phones, smartphones, tablet personal computers (PCs), mobile communication terminals, electronic notebooks, electronic books, portable multimedia players (PMPs), navigation devices, and ultra-mobile PCs (UMPCs). Alternatively, the display device 10 according to the embodiment may be applied as a display unit of a television, a laptop computer, a monitor, a billboard, or an Internet of things (IoT) device. Alternatively, the display device 10 according to the embodiment may be applied to wearable devices such as smart watches, watch phones, glasses-type displays, and head-mounted displays (HMDs). Alternatively, the display device 10 according to the embodiment may be applied to an instrument cluster of a vehicle, a center fascia of a vehicle, a center information display (CID) located on a dashboard of a vehicle, a room mirror display replacing side mirrors of a vehicle, or a display located on the back of a front seat as an entertainment for rear-seat passengers of a vehicle.

The display device 10 according to the embodiment may be a light emitting display device such as an organic light emitting display device using an organic light emitting diode, a quantum dot light emitting display device including a quantum dot light emitting layer, an inorganic light emitting display device including an inorganic semiconductor, or an ultrasmall light emitting display device including an ultrasmall light emitting diode (a micro- or nano-light emitting diode). A case where the display device 10 according to the embodiment is an organic light emitting display device will be mainly described below, but the present disclosure is not limited to this case.

The display device 10 according to the embodiment includes a display panel 100, a display driving circuit 200, a display circuit board 300, and a touch driving circuit 400.

The display panel 100 may be shaped like a rectangular plane having short sides in a first direction (X-axis direction) and long sides in a second direction (Y-axis direction) which intersects the first direction (X-axis direction). Each corner where a short side extending in the first direction (X-axis direction) meets a long side extending in the second direction (Y-axis direction) may be rounded in the plan view to have a selected curvature or may be right-angled. The planar shape of the display panel 100 is not limited to a quadrangular shape but may also be other polygonal shapes, a circular shape, or an elliptical shape. A plane may be defined by the first direction and the second direction intersecting each other, e.g., an XY plane.

The display panel 100 may be formed (or provided) flat, but the present disclosure is not limited to this case. For example, the display panel 100 disposed in the XY plane includes a curved portion formed at left and right ends and having a constant or varying curvature. In addition, the display panel 100 may be formed to be flexible so that it can be curved, bent, folded, or rolled.

The display panel 100 includes a main area MA and a sub-area SBA.

The main area MA includes a display area DA displaying an image and a non-display area NDA which is adjacent to the display area DA, such as being located around the display area DA in the plan view. The display area DA includes pixels PX which display an image. The sub-area SBA may protrude from a side of the main area MA in the second direction (Y-axis direction). The main area MA and the sub-area SBA may define an overall planar area of the display panel 100.

Although the sub-area SBA is unfolded in FIGS. 1 and 2, it may also be bent as illustrated in FIG. 3. In this case, the display panel 100 which is bent at the sub-area SBA includes the sub-area SBA placed on a lower surface of the display panel 100. When the sub-area SBA is bent, it may be overlapped by the main area MA in a third direction (Z-axis direction) which is a thickness direction of the display device 10 and/or various components or layers thereof, such as a substrate SUB. The display driving circuit 200 may be located in the sub-area SBA. As being overlapping, elements may be disposed along a same line in a direction, such as along a thickness direction, a lateral direction, etc. For example, one element may be above or below another element along a thickness direction, so as to be be considered overlapping each other, without being limited thereto.

In addition, the display panel 100 includes the substrate SUB, a thin-film transistor layer TFTL as a circuit layer, a light emitting element layer EML as a display element layer connected to the circuit layer, an encapsulation layer TFEL, a touch sensing unit TDU, and an optical layer OPL as illustrated in FIG. 3.

The thin-film transistor layer TFTL may be located on the substrate SUB. The thin-film transistor layer TFTL may be located in the main area MA and the sub-area SBA. The thin-film transistor layer TFTL includes thin-film transistors.

The light emitting element layer EML may be located on the thin-film transistor layer TFTL. The light emitting element layer EML may be located in the display area DA of the main area MA. The light emitting element layer EML includes light emitting elements located in emission portions of the display panel 100. The light emitting layer EML may be (electrically) connected to the thin-film transistor layer TFTL.

The encapsulation layer TFEL may be located on the light emitting element layer EML. The encapsulation layer TFEL may be located in the display area DA and the non-display area NDA of the main area MA. The encapsulation layer TFEL includes at least one inorganic layer and at least one organic layer to encapsulate the light emitting element layer EML.

The touch sensing unit TDU as a touch sensing layer may be located on the encapsulation layer TFEL. The touch sensing unit TDU may be located in the display area DA and the non-display area NDA of the main area MA. The touch sensing unit TDU may detect an external input such as a touch or contact from an input tool such as a body part of a person or an object, using touch electrodes of the touch sensing unit TDU.

The optical layer OPL may be located on the touch sensing unit TDU. The optical layer OPL may be located in the display area DA and the non-display area NDA of the main area MA.

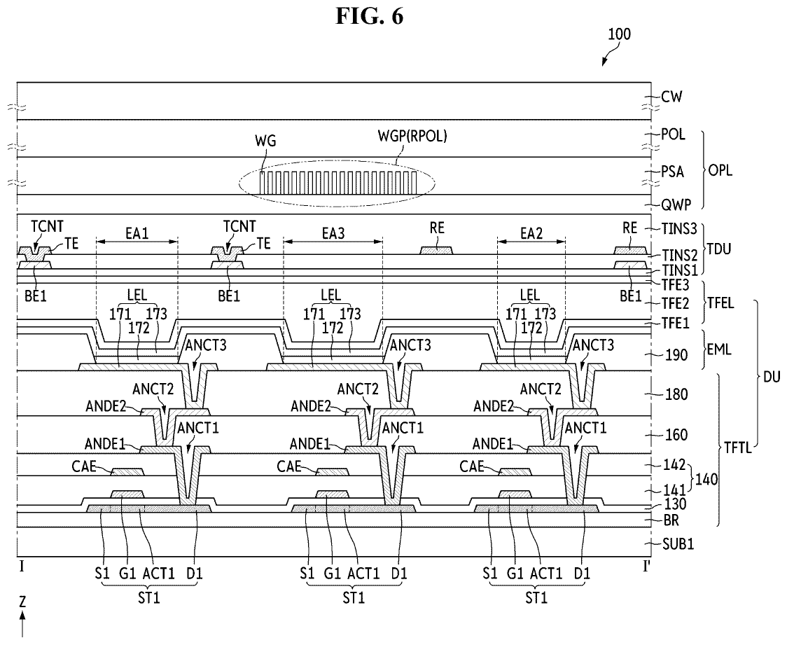

The optical layer OPL may prevent a decrease in the visibility of a displayed image due to reflection of light incident from the outside (e.g., external light from outside of the display device 10). The optical layer OPL may include a phase retardation layer QWP (see FIG. 6), an adhesive layer PSA (see FIG. 6), a reflective polarizing member RPOL (see FIG. 6), and an absorptive polarizing member POL (see FIG. 6), which will be described in detail later with reference to FIG. 6.

A cover window CW may be located on the optical layer OPL to protect an upper part of the display panel 100. The cover window CW may be attached onto the optical layer OPL by a transparent adhesive member such as an optically clear adhesive (OCA) film or an optically clear resin (OCR). The cover window CW may be an inorganic material such as glass or may be an organic material such as plastic or a polymer material.

The display driving circuit 200 may generate (electrical) signals and voltages for driving the display panel 100. The display driving circuit 200 may be formed as an integrated circuit and attached onto the display panel 100 using a chip-on-glass (COG) method, a chip-on-plastic (COP) method, or an ultrasonic bonding method. However, the present disclosure is not limited to this case. For example, the display driving circuit 200 may also be attached onto the display circuit board 300 using a chip-on-film (COF) method.

The display circuit board 300 may be attached to an end of the sub-area SBA of the display panel 100. Accordingly, the display circuit board 300 may be electrically connected to the display panel 100 and the display driving circuit 200. The display panel 100 and the display driving circuit 200 may receive digital video data, timing signals, and driving voltages through the display circuit board 300. The display circuit board 300 may be a flexible printed circuit board, a printed circuit board, or a flexible film such as a chip-on-film.

The touch driving circuit 400 may be located on the display circuit board 300. The touch driving circuit 400 may be formed as an integrated circuit and attached to the display circuit board 300.

The touch driving circuit 400 may be electrically connected to a plurality of driving electrodes and a plurality of sensing electrodes of the touch sensing unit TDU. The touch driving circuit 400 applies a touch driving signal to the driving electrodes and detects the amount of charge change in the mutual capacitance of each of a plurality of touch nodes through the sensing electrodes. The touch driving circuit 400 may determine whether a touch or proximity of an input tool such as from a user has occurred based on the amount of charge change in the mutual capacitance of each of the touch nodes. The touch of the user refers to a direct contact of the user's finger or an object, such as a pen, with a surface of the cover window CW located on the touch sensing unit TDU. The proximity of the user refers to hovering of the user's finger or an object, such as a pen, over the surface of the cover window CW.

The layers of the substrate SUB, the circuit layer (like TFTL), the display element layer (like EML) and the encapsulation layer (like TFEL), may together define an image display unit DU.

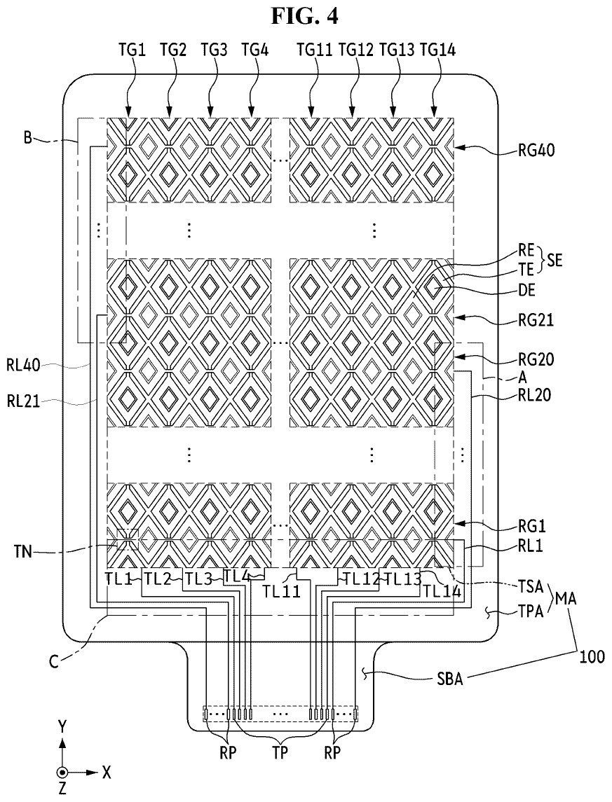

FIG. 4 is a schematic plan view of a touch sensing unit TDU of FIG. 3 according to an embodiment.

In FIG. 4, the touch sensing unit TDU may include sensor electrodes SE, and the sensor electrodes SE may include driving electrodes TE and sensing electrodes RE. A case where the touch sensing unit TDU is driven by a mutual capacitance method will be mainly described below. In the mutual capacitance method, the touch sensing unit TDU applies a touch driving signal to the driving electrodes TE and then detects the amount of charge change in the mutual capacitance of each of a plurality of touch nodes through the sensing electrodes RE.

Referring to FIG. 4, the touch sensing unit TDU includes a touch sensing area TSA for sensing a user's touch and a touch peripheral area TPA which is adjacent to the touch sensing area TSA, such as being located around the touch sensing area TSA. The touch sensing area TSA may overlap the display area DA of FIGS. 1 through 3, and the touch peripheral area TPA may overlap the non-display area NDA of FIGS. 1 through 3.

The touch sensing unit TDU includes a plurality of driving electrode groups TG1 through TG14, a plurality of sensing electrode groups RG1 through RG40, a plurality of driving lines TL1 through TL14, a plurality of sensing lines RL1 through RL40, a plurality of driving pads TP, and a plurality of sensing pads RP.

The driving electrode groups TG1 through TG14 and the sensing electrode groups RG1 through RG40 may be located in the touch sensing area TSA. The driving lines TL1 through TL14, the sensing lines RL1 through RL40, the driving pads TP, and the sensing pads RP may be located in the touch peripheral area TPA.

The driving electrode groups TG1 through TG14 may be arranged in the first direction (X-axis direction). The driving electrode groups TG1 through TG14 may be arranged from the left to the right of the touch sensing area TSA. For example, a first driving electrode group TG1 may be located at the far left of the touch sensing area TSA, a second driving electrode group TG2 may be located on a right side of the first driving electrode group TG1, a third driving electrode group TG3 may be located on a right side of the second driving electrode group TG2, and a fourth driving electrode group TG4 may be located on a right side of the third driving electrode group TG3. In addition, a fourteenth driving electrode group TG14 may be located at the far right of the touch sensing area TSA, a thirteenth driving electrode group TG13 may be located on a left side of the fourteenth driving electrode group TG14, a twelfth driving electrode group TG12 may be located on a left side of the thirteenth driving electrode group TG13, and an eleventh driving electrode group TG11 may be located on a left side of the twelfth driving electrode group TG12. The first driving electrode group TG1 and the fourteenth driving electrode group TG14 may be respectively considered an outermost driving electrode group along the first direction.

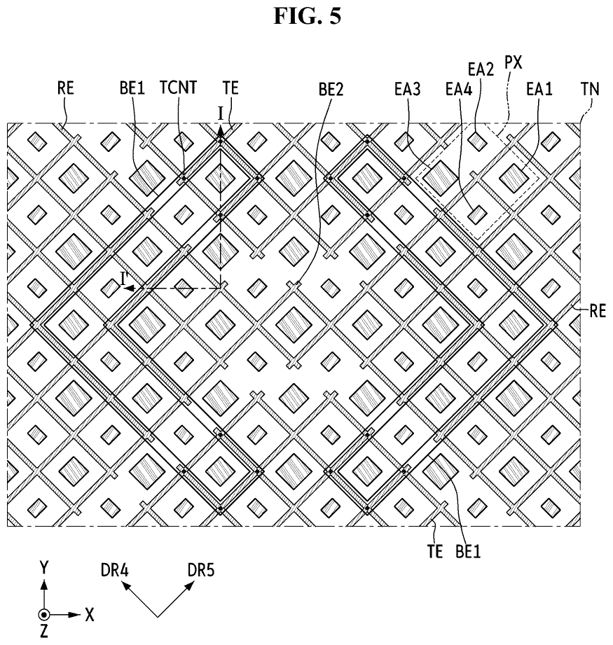

The driving electrode groups TG1 through TG14 may be electrically isolated from each other. Each of the driving electrode groups TG1 through TG14 includes a plurality of driving electrodes TE electrically connected to each other in the second direction (Y-axis direction). The driving electrodes TE neighboring each other in the second direction (Y-axis direction) may be connected to each other through a first connector BE1 as illustrated in FIG. 5.

Each of the driving electrode groups TG1 through TG14 may be connected to a corresponding driving line on a lower side of the touch sensing area TSA. For example, the first driving electrode group TG1 may be connected to a first driving line TL1, the second driving electrode group TG2 may be connected to a second driving line TL2, the third driving electrode group TG3 may be connected to a third driving line TL3, and the fourth driving electrode group TG4 may be connected to a fourth driving line TL4. The eleventh driving electrode group TG11 may be connected to an eleventh driving line TL11, the twelfth driving electrode group TG12 may be connected to a twelfth driving line TL12, the thirteenth driving electrode group TG13 may be connected to a thirteenth driving line TL13, and the fourteenth driving electrode group TG14 may be connected to a fourteenth driving line TL14.

In FIG. 4, fifth through tenth driving electrode groups and fifth through tenth driving lines are omitted for ease of description. In addition, although the touch detection area TSA includes fourteen driving electrode groups TG1 through TG14 and fourteen driving lines TL1 through TL14 in FIG. 4, the number of driving electrode groups TG1 through TG14 is not limited to this example.

The sensing electrode groups RG1 through RG40 may be arranged in the second direction (Y-axis direction). The sensing electrode groups RG1 through RG40 may be arranged from the bottom to the top of the touch sensing area TSA. For example, a first sensing electrode group RG1 may be located at the bottom of the touch sensing area TSA, and a fortieth sensing electrode group RG40 may be located at the top of the touch sensing area TSA. Each of the first sensing electrode group RG1 and the fortieth sensing electrode group RG40 may be an outermost sensing electrode group.

The sensing electrode groups RG1 through RG40 may be electrically isolated from each other. Each of the sensing electrode groups RG1 through RG40 includes a plurality of sensing electrodes RE electrically connected to each other in the first direction (X-axis direction). The sensing electrodes RE neighboring each other in the first direction (X-axis direction) may be connected to each other through a second connector BE2 as illustrated in FIG. 5.

Each of first through twentieth sensing electrode groups RG1 through RG20 among the sensing electrode groups RG1 through RG40 may be connected to a corresponding sensing line on a right side of the touch sensing area TSA. For example, the first sensing electrode group RG1 may be connected to a first sensing line RL1, and the twentieth sensing electrode group RG20 may be connected to a twentieth sensing line RL20.

Each of twenty-first through fortieth sensing electrode groups RG21 through RG40 among the sensing electrode groups RG1 through RG40 may be connected to a corresponding sensing line on a left side of the touch sensing area TSA. For example, the twenty-first sensing electrode group RG21 may be connected to a twenty-first sensing line RL21, and the fortieth sensing electrode group RG40 may be connected to a fortieth sensing line RL40.

In FIG. 4, second through nineteenth sensing electrode groups, twenty-first through thirty-ninth sensing electrode groups, second through nineteenth sensing lines, and twenty-first through thirty-ninth sensing lines are omitted for ease of description. In addition, although the touch sensing area TSA includes forty sensing electrode groups RG1 through RG40 and forty sensing lines RL1 through RL40 in FIG. 4, the number of sensing electrode groups RG1 through RG40 and the number of sensing lines RL1 through RL40 are not limited to this example.

Since the driving electrode groups TG1 through TG14 and the sensing electrode groups RG1 through RG40 are electrically isolated, a touch node TN, in which mutual capacitance is formed, may be located at each of the intersections of the driving electrode groups TG1 through TG14 and the sensing electrode groups RG1 through RG40. In this case, the mutual capacitance of each of the touch nodes TN may be charged by applying a touch driving signal to the driving electrode groups TG1 through TG14. In addition, the amount of change in the mutual capacitance of each of the touch nodes TN may be detected through the sensing electrode groups RG1 through RG40.

Each of a plurality of dummy patterns DE may be surrounded by a driving electrode TE or a sensing electrode RE. Each of the dummy patterns DE may be electrically isolated from a respective one of the driving electrode TE or the sensing electrode RE. Each of the dummy patterns DE may be spaced apart from the driving electrode TE or the sensing electrode RE. Each of the dummy patterns DE may electrically float.

In FIG. 4, each of the driving electrodes TE, the sensing electrodes RE, and the dummy patterns DE has a rhombic planar shape. However, the present disclosure is not limited to this case. For example, each of the driving electrodes TE, the sensing electrodes RE, and the dummy patterns DE may also be shaped like a quadrangle other than a rhombus, a polygon other than a quadrangle, a circle, or an ellipse in a plan view.

The driving lines TL1 through TL14 may be located on the lower side of the touch sensing area TSA. Some of the sensing lines RL1 through RL40 may be located on the right side of the touch sensing area TSA, and the rest may be located on the left side of the touch sensing area TSA. For example, the first through twentieth sensing lines RL1 through RL20 may be located on the right side of the touch sensing area TSA, and the twenty-first through fortieth touch sensing lines RL21 through RL40 may be located on the left side of the touch sensing area TSA. The first through twentieth sensing lines RL1 through RL20 may be defined as a first sensing line group RLG1, and the twenty-first through fortieth sensing lines RL21 through RL40 may be defined as a second sensing line group RLG2.

A length of any one of the first through twentieth sensing lines RL1 through RL20 may be smaller than a length of any one of the twenty-first through fortieth touch sensing lines RL21 through RL40. A maximum wiring length of the first through twentieth sensing lines RL1 through RL20 may be smaller than a minimum wiring length of the twenty-first through fortieth touch sensing lines RL21 through RL40.

In FIG. 4, the number of sensing lines located on the right side of the touch sensing area TSA and the number of sensing lines located on the left side of the touch sensing area TSA are equal. However, embodiments of the present specification are not limited to this case. For example, the number of sensing lines located on the right side of the touch sensing area TSA and the number of sensing lines located on the left side of the touch sensing area TSA may also be different. That is, the number of sensing lines located on the right side of the touch sensing area TSA may be greater than the number of sensing lines located on the left side of the touch sensing area TSA.

Each of the driving pads TP may be connected to a corresponding driving line among the driving lines TL1 through TL14. Each of the sensing pads RP may be connected to a corresponding sensing line among the sensing lines RL1 through RL40. The driving pads TP and the sensing pads RP may be located in the sub-area SBA. The driving pads TP and the sensing pads RP may be electrically connected to the display circuit board 300 through a conductive adhesive member such as an anisotropic conductive film.

FIG. 5 is an enlarged plan view illustrating a touch node TN of FIG. 4 according to an embodiment.

Referring to FIG. 5, a touch node TN may be defined as an intersection of a driving electrode TE and a sensing electrode RE.

Since a plurality of driving electrodes TE and a plurality of sensing electrodes RE are located in the same layer, they may be spaced apart from each other. That is, a gap may be formed between a driving electrode TE and a sensing electrode RE adjacent to each other.

In addition, a plurality of dummy patterns DE may be located in the same layer as the driving electrodes TE and the sensing electrodes RE. That is, a gap may be formed between a driving electrode TE and a dummy pattern DE adjacent to each other and between a sensing electrode RE and a dummy pattern DE adjacent to each other, in the plan view. As being in a same layer, elements may be formed in a same process and/or include a same material as each other, elements may be respective portions of a same material layer, elements may be on a same layer by forming an interface with a same underlying or overlying layer, elements may be coplanar with each other or be disposed in a same thickness, etc., without being limited thereto.

A plurality of first connectors BE1 may be located in a different layer from the driving electrodes TE and the sensing electrodes RE. The first connectors BE1 may be bent at least once. In FIG. 5, each of the first connectors BE1 may be shaped like a bracket (“<” or “>”) in the plan view. However, the planar shape of each of the first connectors BE1 is not limited to this example. The material portion of the first connector BE1 may form an enclosed loop in the plan view, without being limited thereto, the enclosed loop having an overall bracket shape discussed above.

The driving electrodes TE adjacent to each other in the second direction (Y-axis direction) may be connected by a plurality of first connectors BE1. Therefore, even if any one of the first connectors BE1 is broken, the connection between the driving electrodes TE adjacent to each other in the second direction (Y-axis direction) may be maintained. In FIG. 5, the driving electrodes TE adjacent to each other are connected by two first connectors BE1, but the number of first connectors BE1 is not limited to this example.

Each of the first connectors BE1 may overlap driving electrodes TE, which are adjacent to each other in the second direction (Y-axis direction), in the third direction (Z-axis direction) which is the thickness direction of the substrate SUB. Each of the first connectors BE1 may overlap a sensing electrode RE in the third direction (Z-axis direction). A side of a first connector BE1 may be connected to any one of the driving electrodes TE, which are adjacent to each other in the second direction (Y-axis direction), through touch contact holes TCNT. The other side of the first connector BE1 may be connected to the other one of the driving electrodes TE, which are adjacent to each other in the second direction (Y-axis direction), through touch contact holes TCNT.

Due to the first connectors BE1, the driving electrodes TE and the sensing electrodes RE may be electrically isolated at their respective intersections. As a result, mutual capacitance may be formed at each of the intersections of the driving electrodes TE and the sensing electrodes RE.

Each of the driving electrodes TE, the sensing electrodes RE, and the first connectors BE1 may have a mesh structure or a net structure in the plan view. In addition, each of the dummy patterns DE may have a mesh structure or a net structure in the plan view. As a mesh structure, material portions of a respective electrode or connector may be spaced apart from each other with a gap therebetween. Accordingly, each of the driving electrodes TE, the sensing electrodes RE, the first connectors BE1, and the dummy patterns DE may not overlap a plurality of emission portions EA1 through EA4 of each of a plurality of pixels PX.

For example, the various emission portions as (light) emission areas may be located at the gap between material portions of a respective electrode, connector, pattern, etc. Therefore, it is possible to prevent light emitted from the emission portions EA1 through EA4 from being blocked by the material of the driving electrodes TE, the sensing electrodes RE, the first connectors BE1 and the dummy patterns DE and thus being reduced in luminance.

Each of the pixels PX includes a plurality of emission areas such as a first emission portion EA1 which emits light of a first color, a second emission portion EA2 which emits light of a second color, a third emission portion EA3 which emits light of a third color, and a fourth emission portion EA4 which emits light of the second color. For example, the first color may be red, the second color may be green, and the third color may be blue.

The first emission portion EA1 and the second emission portion EA2 of each of the pixels PX may neighbor each other in a fourth direction DR4, and the third emission portion EA3 and the fourth emission portion EA4 may neighbor each other in the fourth direction DR4. The first emission portion EA1 and the fourth emission portion EA4 of each of the pixels PX may neighbor each other in a fifth direction DR5, and the second emission portion EA2 and the third emission portion EA3 may neighbor each other in the fifth direction DR5.

Each of the first emission portion EA1, the second emission portion EA2, the third emission portion EA3, and the fourth emission portion EA4 may have a rhombic planar shape or a rectangular planar shape. However, the present disclosure is not limited to this case. Each of the first emission portion EA1, the second emission portion EA2, the third emission portion EA3, and the fourth emission portion EA4 may also be shaped like a polygon other than a quadrangle, a circle, or an ellipse in the plan view. In addition, in FIG. 5, the area (e.g., planar area) of the third emission portion EA3 is the largest, and the areas of the second emission portion EA2 and the fourth emission portion EA4 are the smallest, but the present disclosure is not limited to this case.

The second emission portions EA2 and the fourth emission portions EA4 may be arranged in odd rows. The second emission portions EA2 and the fourth emission portions EA4 may be arranged side by side in the first direction (X-axis direction) in each of the odd rows, where the row extends along the first direction. The second emission portions EA2 and the fourth emission portions EA4 may be arranged alternately in each of the odd rows. Within a same row, each of the second emission portions EA2 may have short sides in the fourth direction DR4 and long sides in the fifth direction DR5, while each of the fourth emission portions EA4 has long sides in the fourth direction DR4 and short sides in the fifth direction DR5. The fourth direction DR4 may be a direction between the first direction (X-axis direction) and the second direction (Y-axis direction) and may be a direction inclined at 45 degrees with respect to the first direction (X-axis direction). The fifth direction DR5 may be a direction orthogonal to the fourth direction DR4.

The first emission portions EA1 and the third emission portions EA3 may be arranged in even rows. The first emission portions EA1 and the third emission portions EA3 may be arranged side by side in the first direction (X-axis direction) in each of the even rows. The first emission portions EA1 and the third emission portions EA3 may be arranged alternately in each of the even rows.

The second emission portions EA2 and the fourth emission portions EA4 may be arranged in odd columns. The second emission portions EA2 and the fourth emission portions EA4 may be arranged side by side in the second direction (Y-axis direction) in each of the odd columns. The second emission portions EA2 and the fourth emission portions EA4 may be arranged alternately in each of the odd columns.

The first emission portions EA1 and the third emission portions EA3 may be arranged in even columns. The first emission portions EA1 and the third emission portions EA3 may be arranged side by side in the second direction (Y-axis direction) in each of the even columns. The first emission portions EA1 and the third emission portions EA3 may be arranged alternately in each of the even columns.

FIG. 6 is a cross-sectional view of the display panel 100 taken along line I-I′ of FIG. 5 according to an embodiment.

Referring to FIG. 6, a barrier layer BR may be located on a substrate SUB1. The substrate SUB1 may include an insulating material such as polymer resin. For example, the substrate SUB1 may include polyimide. The substrate SUB1 may be a flexible substrate which can be bent, folded, rolled, etc.

The barrier layer BR is a layer for protecting transistors of a thin-film transistor layer TFTL and light emitting layers 172 of a light emitting element layer EML from moisture introduced through the substrate SUB1 which is vulnerable to moisture penetration. The barrier layer BR may include a plurality of inorganic layers stacked alternately. For example, the barrier layer BR may be a multilayer in which one or more inorganic layers selected from a silicon nitride layer, a silicon oxynitride layer, a silicon oxide layer, a titanium oxide layer, and an aluminum oxide layer are alternately stacked.

Thin-film transistors ST1 may be located on the barrier layer BR. Each of the thin-film transistors ST1 includes an active layer ACT1, a gate electrode G1, a source electrode S1, and a drain electrode D1.

The active layer ACT1, the source electrode S1, and the drain electrode D1 of each of the thin-film transistors ST1 may be located on the barrier layer BR. The active layer ACT1 of each of the thin-film transistors ST1 includes polycrystalline silicon, monocrystalline silicon, low-temperature polycrystalline silicon, amorphous silicon, or an oxide semiconductor. The active layer ACT1, which is overlapped by the gate electrode G1 in the third direction (Z-axis direction), e.g., the thickness direction of the substrate SUB1, may be defined as a channel region. The source electrode S1 and the drain electrode D1 may regions not overlapped by the gate electrode G1 in the third direction (Z-axis direction). The source region S1 and the drain region D1 may be regions formed to have conductivity by doping a silicon semiconductor or an oxide semiconductor with ions or impurities.

Agate insulating layer 130 may be located on the active layer ACT1, the source electrode S1, and the drain electrode D1 of each of the thin-film transistors ST1. The gate insulating layer 130 may include an inorganic layer, for example, a silicon nitride layer, a silicon oxynitride layer, a silicon oxide layer, a titanium oxide layer, or an aluminum oxide layer.

The gate electrode G1 of each of the thin-film transistors ST1 may be located on the gate insulating layer 130. The gate electrode G1 may overlap an active layer ACT1 in the third direction (Z-axis direction). The gate electrode G1 may be a single layer or a multilayer including any one or more of molybdenum (Mo), aluminum (Al), chromium (Cr), gold (Au), titanium (Ti), nickel (Ni), neodymium (Nd), copper (Cu), and alloys thereof.

A first interlayer insulating film 141 may be located on the gate electrodes G1 of the thin-film transistors ST1. The first interlayer insulating film 141 may include an inorganic layer, for example, a silicon nitride layer, a silicon oxynitride layer, a silicon oxide layer, a titanium oxide layer, or an aluminum oxide layer. The first interlayer insulating film 141 may include a plurality of inorganic layers.

Capacitor electrodes CAE may be located on the first interlayer insulating film 141. The capacitor electrodes CAE may overlap the gate electrodes G1 of the thin-film transistors ST1 in the third direction (Z-axis direction). Since the first interlayer insulating film 141 has a selected dielectric constant, capacitors may be formed by the capacitor electrodes CAE, the gate electrodes G1, and the first interlayer insulating film 141 located between them. Each of the capacitor electrodes CAE may be a single layer or a multilayer including any one or more of molybdenum (Mo), aluminum (Al), chromium (Cr), gold (Au), titanium (Ti), nickel (Ni), neodymium (Nd), copper (Cu), and alloys thereof.

A second interlayer insulating film 142 may be located on the capacitor electrodes CAE. The second interlayer insulating film 142 may include an inorganic layer, for example, a silicon nitride layer, a silicon oxynitride layer, a silicon oxide layer, a titanium oxide layer, or an aluminum oxide layer. The second interlayer insulating film 142 may include a plurality of inorganic layers. The first interlayer insulating film 141 and the second interlayer insulating film 142 may together be considered an interlayer insulating film 140.

First anode connection electrodes ANDE1 may be located on the second interlayer insulating film 142. Each of the first anode connection electrodes ANDE1 may be connected to the drain region D1 of a thin-film transistor ST1 through a first connection contact hole ANCT1 penetrating the gate insulating layer 130, the first interlayer insulating film 141 and the second interlayer insulating film 142. Each of the first anode connection electrodes ANDE1 may be a single layer or a multilayer including any one or more of molybdenum (Mo), aluminum (Al), chromium (Cr), gold (Au), titanium (Ti), nickel (Ni), neodymium (Nd), copper (Cu), and alloys thereof.

A first planarization layer 160 may be located on the first anode connection electrodes ANDE1 to flatten steps due to the thin-film transistors ST1. The first planarization layer 160 may include an organic layer such as acryl resin, epoxy resin, phenolic resin, polyamide resin, or polyimide resin.

Second anode connection electrodes ANDE2 may be located on the first planarization layer 160. Each of the second anode connection electrodes ANDE2 may be connected to a first anode connection electrode ANDE1 through a second connection contact hole ANCT2 penetrating the first planarization layer 160. Each of the second anode connection electrodes ANDE2 may be a single layer or a multilayer including any one or more of molybdenum (Mo), aluminum (Al), chromium (Cr), gold (Au), titanium (Ti), nickel (Ni), neodymium (Nd), copper (Cu), and alloys thereof.

A second planarization layer 180 may be located on the second anode connection electrodes ANDE2. The second planarization layer 180 may include an organic layer such as acryl resin, epoxy resin, phenolic resin, polyamide resin, or polyimide resin.

Light emitting elements LEL and a bank 190 may be located on the second planarization layer 180. Each of the light emitting elements LEL includes a pixel electrode 171, a light emitting layer 172, and a common electrode 173.

The pixel electrode 171 may be located on the second planarization layer 180. The pixel electrode 171 may be connected to each of the second anode connection electrodes ANDE2 through a third connection contact hole ANCT3 penetrating the second planarization layer 180.

In a top emission structure in which light is emitted from the light emitting layer 172 toward the common electrode 173, the pixel electrode 171 may include a metal material having high reflectivity, such as a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide. The APC alloy is an alloy of silver (Ag), palladium (Pd), and copper (Cu).

The bank 190 may be formed on the second planarization layer 180 to separate the pixel electrodes 171 in order to define a first emission portion EA1, a second emission portion EA2, a third emission portion EA3 and a fourth emission portion EA4. A planar area of the various emission areas (portions) may be defined by a dimension of a bank opening defined by the bank 190. The bank 190 may cover edges of the pixel electrodes 171. The bank 190 may include an organic layer such as acryl resin, epoxy resin, phenolic resin, polyamide resin, or polyimide resin. The solid (material) portion of the bank 190 together with the bank opening may provide a bank layer.

Each of the first emission portion EA1, the second emission portion EA2, the third emission portion EA3, and the fourth emission portion EA4 is an area in which the pixel electrode 171, the light emitting layer 172, and the common electrode 173 are sequentially stacked and overlap each other, so that holes from the pixel electrode 171 and electrons from the common electrode 173 are combined with each other in the light emitting layer 172 to emit light at the various emission areas.

The light emitting layer 172 may be located on the pixel electrode 171 and the bank 190. The light emitting layer 172 may include an organic material to emit light of a selected color. For example, the light emitting layer 172 includes one or more of a hole transporting layer, an organic material layer, and an electron transporting layer.

The common electrode 173 may be located on the light emitting layers 172. The common electrode 173 may cover the light emitting layers 172. The common electrode 173 may be a common layer formed in common in the first emission portion EA1, the second emission portion EA2, the third emission portion EA3, and the fourth emission portion EA4. A capping layer (not shown) may be formed on the common electrode 173.

In the top emission structure, the common electrode 173 may include a transparent conductive material (TCO) which can transmit light, such as indium tin oxide (ITO) or indium zinc oxide (IZO), or a semi-transmissive conductive material such as magnesium (Mg), silver (Ag) or an alloy of Mg and Ag. When the common electrode 173 includes a semi-transmissive conductive material, light output efficiency may be increased by a microcavity.

An encapsulation layer TFEL may be located on the common electrode 173. The encapsulation layer TFEL includes at least one inorganic layer to prevent oxygen or moisture from permeating into the light emitting element layer EML. In addition, the encapsulation layer TFEL includes at least one organic layer to protect the light emitting element layer EML from foreign substances such as dust. For example, the encapsulation layer TFEL includes a first encapsulating inorganic layer TFE1, an encapsulating organic layer TFE2, and a second encapsulating inorganic layer TFE3.

The first encapsulating inorganic layer TFE1 may be located on the common electrode 173, the encapsulating organic layer TFE2 may be located on the first encapsulating inorganic layer TFE1, and the second encapsulating inorganic layer TFE3 may be located on the encapsulating organic layer TFE2. Each of the first encapsulating inorganic layer TFE1 and the second encapsulating inorganic layer TFE3 may be a multilayer in which one or more inorganic layers selected from a silicon nitride layer, a silicon oxynitride layer, a silicon oxide layer, a titanium oxide layer, and an aluminum oxide layer are alternately stacked. The encapsulating organic layer TFE2 may be an organic layer such as acryl resin, epoxy resin, phenolic resin, polyamide resin, or polyimide resin.

A touch sensing unit TDU may be located on the encapsulation layer TFEL. The touch sensing unit TDU includes a first touch insulating layer TINS1, first connectors BE1, a second touch insulating layer TINS2, driving electrodes TE, sensing electrodes RE, and a third touch insulating layer TINS3.

The first touch insulating layer TINS1 may include an inorganic layer, for example, a silicon nitride layer, a silicon oxynitride layer, a silicon oxide layer, a titanium oxide layer, or an aluminum oxide layer.

The first connectors BE1 may be located on the first touch insulating layer TINS1. The first connectors BE1 may be in a same layer as each other, such as being respective portions of a same material layer. Each of the first connectors BE1 may be a single layer or a multilayer including any one or more of molybdenum (Mo), aluminum (Al), chromium (Cr), gold (Au), titanium (Ti), nickel (Ni), neodymium (Nd), copper (Cu), and alloys thereof.

The second touch insulating layer TINS2 is located on the first connectors BEL The second touch insulating layer TINS2 may include an inorganic layer, for example, a silicon nitride layer, a silicon oxynitride layer, a silicon oxide layer, a titanium oxide layer, or an aluminum oxide layer. Alternatively, the second touch insulating layer TINS2 may include an organic layer such as acryl resin, epoxy resin, phenolic resin, polyamide resin, or polyimide resin.

The driving electrodes TE and the sensing electrodes RE may be located on the second touch insulating layer TINS2. In addition to the drive electrodes TE and the sensing electrodes RE, the dummy patterns DE, the driving lines TL1 through TL14, the sensing lines RL1 through RL40 illustrated in FIG. 4 may be located on the second touch insulating layer TINS2. Each of the driving electrodes TE and the sensing electrodes RE may be a single layer or a multilayer including any one or more of molybdenum (Mo), aluminum (Al), chromium (Cr), gold (Au), titanium (Ti), nickel (Ni), neodymium (Nd), copper (Cu), and alloys thereof.

The driving electrodes TE and the sensing electrodes RE may overlap the first connectors BE1 in the third direction (Z-axis direction). Each of the driving electrodes TE may be connected to a first connector BE1 through touch contact holes TCNT penetrating the second touch insulating layer TINS2.

The third touch insulating layer TINS3 is formed on the driving electrodes TE and the sensing electrodes RE. The third touch insulating layer TINS3 may serve to flatten steps formed by a cross-sectional profile of the driving electrodes TE, the sensing electrodes RE, and the first connectors BE1. The third touch insulating layer TINS3 may include an organic layer such as acryl resin, epoxy resin, phenolic resin, polyamide resin, or polyimide resin.

An optical layer OPL may be located on the touch sensing unit TDU. The optical layer OPL may include one or more of a phase retardation layer QWP, a reflective polarizing member RPOL, an adhesive layer PSA, and an absorptive polarizing member POL.

The phase retardation layer QWP may be located on the touch sensing unit TDU, such as being closest to the touch sensing unit TDU. The phase retardation layer QWP may overlap the emission portions EA1 through EA4. The phase retardation layer QWP may be a quarter-wave (λ/4) plate, but embodiments of the present specification are not limited to this case. In addition, the phase retardation layer QWP may be formed by stretching a film or coating liquid crystals. The phase retardation layer QWP formed by coating liquid crystals will be mainly described below, but embodiments of the present specification are not limited to this example.

The phase retardation layer QWP may include a base member, an alignment layer, and a liquid crystal layer. The alignment layer may be formed by applying an alignment layer forming composition on the base member and drying and curing the composition. The alignment layer may have a thickness of, but not limited to about 0.1 micrometer (μm) to about 0.5 μm.

The base member may include glass or a transparent plastic film. The plastic film may be polyethersulphone (PES), polyacrylate (PAR), polyetherimide (PEI), polyethylene naphthalate (PEN), polyethylene terephthalate (PET), polyphenylene sulfide (PPS), polyallylate, polyimide, polycarbonate (PC), cellulose triacetate (TAC), cellulose acetate propionate (CAP), etc.

The alignment layer forming composition is in the form of a solution in which a polymer, a coupling agent, etc. are dissolved in an organic solvent. The alignment layer forming composition is coated on the base member by spin coating, gravure coating, etc. After the coating, polarized light is irradiated to give an alignment force to the alignment layer in a polarization direction of the polarized light.

The polymer included in the alignment layer forming composition may be a polymer such as polymethyl methacrylate, acrylic acid-methacrylic acid copolymer, styrene-maleimide copolymer, polyvinyl alcohol, modified polyvinyl alcohol, gelatin, styrene-vinyl toluene copolymer, chlorosulfonated polyethylene, nitrocellulose, polyvinyl chloride, chlorinated polyolefin, polyester, polyimide, vinyl acetate-vinyl chloride copolymer, ethylene-vinyl acetate copolymer, carboxymethyl cellulose, polyethylene, polypropylene, or polycarbonate. In addition, the coupling agent may be a silane coupling agent or the like.

The liquid crystal layer may include liquid crystals and reactive liquid crystals. The liquid crystals may be, for example, nematic liquid crystals and may be non-reactive liquid crystals which do not include a reactive group. The reactive liquid crystals are, for example, mesogens which exhibit a nematic liquid crystal phase and include a terminal group capable of radical polymerization. The terminal group capable of polymerization may be an acrylic group, a methacrylic group, etc. For example, the reactive liquid crystals may include monoacrylate-type reactive liquid crystals and diacrylate-type reactive liquid crystals.

The liquid crystal layer may be formed by applying a liquid crystal layer forming composition, which includes liquid crystals and reactive liquid crystals, on the alignment layer and then drying and curing the composition. The liquid crystal layer forming composition is in the form of a solution in which, in addition to the liquid crystals and the reactive liquid crystals, additives such as a polymerization initiator and a curing agent are dissolved in an organic solvent. The liquid crystal layer forming composition is coated on the alignment layer by spin coating, gravure coating, etc., and then cured.

When ultraviolet light is irradiated to the liquid crystal layer forming composition applied on the alignment layer, the reactive liquid crystals are polymerized and aligned in the same direction as the alignment direction of the alignment layer, and an optical axis is formed according to the alignment direction of the alignment layer. In addition, the liquid crystals without a reactive group in the liquid crystal layer forming composition are arranged in the same direction as the direction in which the reactive liquid crystals are arranged through x-x interaction with the reactive liquid crystals which form the optical axis. Accordingly, the liquid crystal layer may function as a λ/4 phase film. The liquid crystal layer may be formed by a coating process.

In the embodiment of the present specification, a case where the phase retardation layer QWP includes the base member is described as an example. However, the base member may be removed after a manufacturing process or attachment process of the phase retardation layer QWP.

The reflective polarizing member RPOL may be located on the phase retardation layer QWP. The reflective polarizing member RPOL may include a plurality of wire grid patterns WGP, and the wire grid patterns WGP may include respective wire grids WG together with the gap defined adjacent wire grids WG. Each of the wire grids WG may be shaped like a rectangle extending along a seventh direction. The wire grids WG may be arranged at regular intervals along a sixth direction to form the wire grid patterns WGP. Here, the intervals between the wire grids WG may be smaller than the wavelength of light incident on the reflective polarizing member RPOL.

The sixth direction may be substantially the same direction within a plane such as as any one of the first direction, the second direction, the fourth direction DR4 and the fifth direction DR5 described above, and the seventh direction may be a direction orthogonal to the sixth direction. Alternatively, the sixth direction may be a direction defined in a plane defined by the first direction and the second direction and may be a direction different from the first direction, the second direction, the fourth direction DR4 and the fifth direction DR5, and the seventh direction may be a direction orthogonal to the sixth direction.

Each of the wire grid patterns WGP may overlap the third emission portion EA3 among the emission portions EA1 through EA4. Each of the wire grid patterns WGP may not overlap the first emission portion EA1, the second emission portion EA2, and the fourth emission portion EA4. As not overlapping, elements may be adjacent to or spaced apart from each other along a planar direction.

Each of the wire grid patterns WGP includes a reflection axis and a transmission axis which are orthogonal to each other. Each of the wire grid patterns WGP may reflect light having an optical axis which vibrates in the same direction as the reflection axis and may transmit light having an optical axis which vibrates in the same direction as the transmission axis. The transmission axis of each of the wire grid patterns WGP may be the sixth direction, and the reflection axis may be the seventh direction. For example, the sixth direction and the seventh direction may be directions orthogonal to each other.

The adhesive layer PSA may be located between the absorptive polarizing member POL and the phase retardation layer QWP and may be attach the absorptive polarizing member POL to the phase retardation layer QWP.

The adhesive layer PSA may cover the wire grid patterns WGP and the phase retardation layer QWP. The adhesive layer PSA may extend into the gaps defined by the wire grids WG.

A thickness of the adhesive layer PSA may be several micrometers, and a thickness of each of the wire grid patterns WGP may be several tens of nanometers. Accordingly, each of the wire grid patterns WGP may be completely covered by the adhesive layer PSA.

The absorptive polarizing member POL may be located on the adhesive layer PSA. The absorptive polarizing member POL may be furthest from the touch sensing unit TDU. The absorptive polarizing member POL may be of a film type or a coating type. In FIG. 6, a case where the absorptive polarizing member POL is of a film type is illustrated as an example. When the absorptive polarizing member POL is of a coating type, it is formed directly on the wire grid patterns WGP and the phase retardation layer QWP. Therefore, the adhesive layer PSA may be removed.

The absorptive polarizing member POL includes an absorption axis and a transmission axis which are orthogonal to each other. The absorptive polarizing member POL may absorb light having an optical axis which vibrates in the same direction as the absorption axis and may transmit light having an optical axis which vibrates in the same direction as the transmission axis. The transmission axis of the absorptive polarizing member POL may be the sixth direction, and the absorption axis may be the seventh direction. For example, the sixth direction and the seventh direction may be directions orthogonal to each other.

A cover window CW may be located on the absorptive polarizing member POL. The cover window CW may be attached onto the absorptive polarizing member POL by a transparent adhesive member such as an optically clear adhesive (OCA) film or an optically clear resin (OCR). The cover window CW may be an inorganic material such as glass or may be an organic material such as plastic or a polymer material.

Since the absorptive polarizing member POL and the reflective polarizing member RPOL have the transmission axis in the sixth direction, first linearly polarized light having an optical axis in the sixth direction among light incident from the outside may pass through the absorptive polarizing member POL and the reflective polarizing member RPOL and enter the phase retardation layer QWP. The first linearly polarized light having the optical axis in the sixth direction refers to light which vibrates in the sixth direction.

The first linearly polarized light incident on the phase retardation layer QWP may be converted into first circularly polarized light, and the first circularly polarized light may travel downward. The first circularly polarized light may be reflected by a plurality of metal electrodes of the display panel 100 which are light reflective, for example, the sensor electrodes SE, the first connectors BE1, the common electrode 173, the pixel electrodes 171, the connection electrodes ANDE1 and ANDE2, the capacitor electrodes CAE, and the gate electrodes G1. At this time, the first circularly polarized light may be converted into second circularly polarized light which is in an opposite direction to the first circularly polarized light.

The second circularly polarized light, which is reflected from the metal electrodes of the display panel 100 and travels upward, may enter the phase retardation layer QWP again. The second circularly polarized light may be converted into second linearly polarized light by the phase retardation layer QWP, and the second linearly polarized light may travel upward. The second linearly polarized light may be orthogonal to the first linearly polarized light. For example, the second linearly polarized light may have an optical axis which vibrates in the seventh direction.

The second linearly polarized light may be blocked by the absorption axis of the absorptive polarizing member POL and the reflection axis of the reflective polarizing member RPOL.

That is, the light incident from the outside and reflected by the metal electrodes may be prevented from being emitted to the outside again, or the emission of the light to the outside may be reduced. Therefore, a decrease in the visibility of a displayed image can be prevented.

In addition, since each of the wire grid patterns WGP can reflect light having an optical axis in the seventh direction, light having an optical axis in the seventh direction among light emitted from the light emitting elements LEL may be reflected by each of the wire grid patterns WGP to travel downward. The second linearly polarized light reflected by the wire grid patterns WGP may be incident on the phase retardation layer QWP.

The second linearly polarized light incident on the phase retardation layer QWP may be converted into the second circularly polarized light, and the second circularly polarized light may travel downward. The second circularly polarized light may be reflected by the metal electrodes of the display panel 100, for example, the sensor electrodes SE, the first connectors BE1, the common electrode 173, the pixel electrodes 171, the connection electrodes ANDE1 and ANDE2, the capacitor electrodes CAE, and the gate electrodes G1. At this time, the second circularly polarized light may be converted into the first circularly polarized light which is in an opposite direction to the second circularly polarized light.

The first circularly polarized light, which is reflected from the metal electrodes of the display panel 100 and travels upward, may enter the phase retardation layer QWP again. The first circularly polarized light may be converted into the first linearly polarized light by the phase retardation layer QWP, and the first linearly polarized light may travel upward. Since the first linearly polarized light has an optical axis in the same direction as the transmission axes of the absorptive polarizing member POL and the reflective polarizing member RPOL, it can pass through the absorptive polarizing member POL and the reflective polarizing member RPOL.

In an embodiment, a display device 10 includes emission areas including light emitting elements, respectively, an encapsulation layer on the light emitting elements, a reflective polarizing member RPOL on the encapsulation layer and including a wire grid pattern WGP which, among incident light from outside the display device, transmits light having an optical axis in a first direction and reflects light having an optical axis in a second direction orthogonal to the first direction, and an absorptive polarizing member POL which is on the reflective polarizing member RPOL and transmits the light having the optical axis in the first direction together with absorbing the light having the optical axis in the second direction.

The wire grid pattern WGP overlaps the third emission area and non-overlaps the first emission area and the second emission area.

In summary, light reflected by the reflective polarizing member RPOL among the light emitted from the light emitting elements LE may be recycled. Therefore, the ratio of light emitted to the outside to the light emitted from the light emitting element LEL, that is, the light efficiency of the light emitting elements LEL may be increased. However, since the reflective polarizing member RPOL has high reflectivity, it may cause a decrease in visibility due to reflection of external light. In FIG. 6, the reflective polarizing member RPOL is placed in the third emission portion EA3 while being excluded from other emission areas such as the first emission portion EA1, the second emission portion EA2 and the fourth emission portion EA4. Therefore, the light efficiency of the third emission portion EA3 may be increased with a minimum increase in reflectivity, compared with when the reflective polarizing member RPOL is placed on each of the emission portions EA1 through EA4.

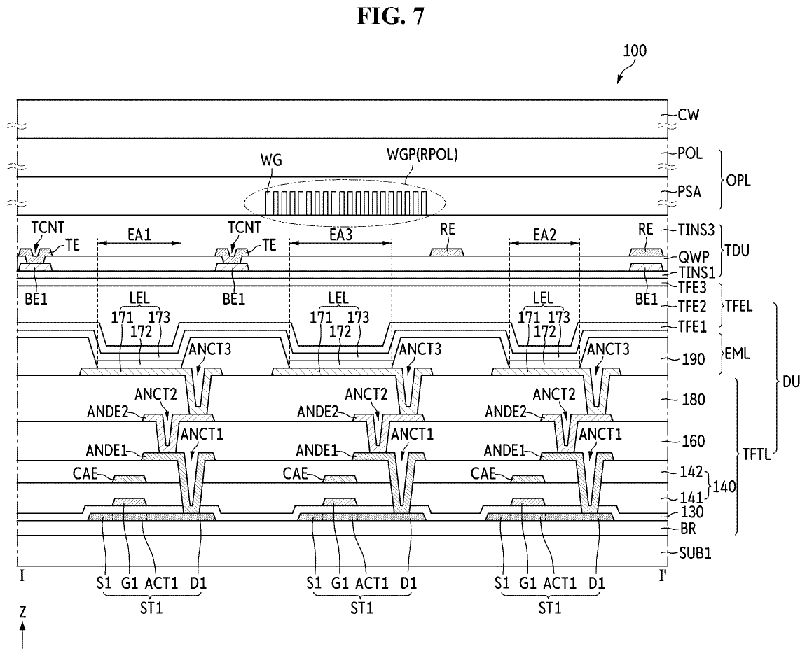

FIGS. 7 through 9 are cross-sectional views of the display panel 100 taken along line I-I′ of FIG. 5 according to embodiments. The position of a phase retardation layer QWP can be adjusted as illustrated in FIGS. 7 through 9 within a range which prevents a decrease in the visibility of a displayed image due to external light and increases the light efficiency of light emitting elements LEL.

FIG. 7 is an embodiment in which the second touch insulating layer TINS2 of FIG. 6 is replaced with a phase retardation layer QWP.

Referring to FIG. 7, the phase retardation layer QWP, instead of the second touch insulating layer TINS2, may be located on first connectors BEL. Driving electrodes TE and sensing electrodes RE may be located on the phase retardation layer QWP. That is, the phase retardation layer QWP may be located between the first connectors BE1 and sensor electrodes SE. In addition, each of the driving electrodes TE may be connected to a corresponding first connector BE1 through touch contact holes TCNT penetrating the phase retardation layer QWP.

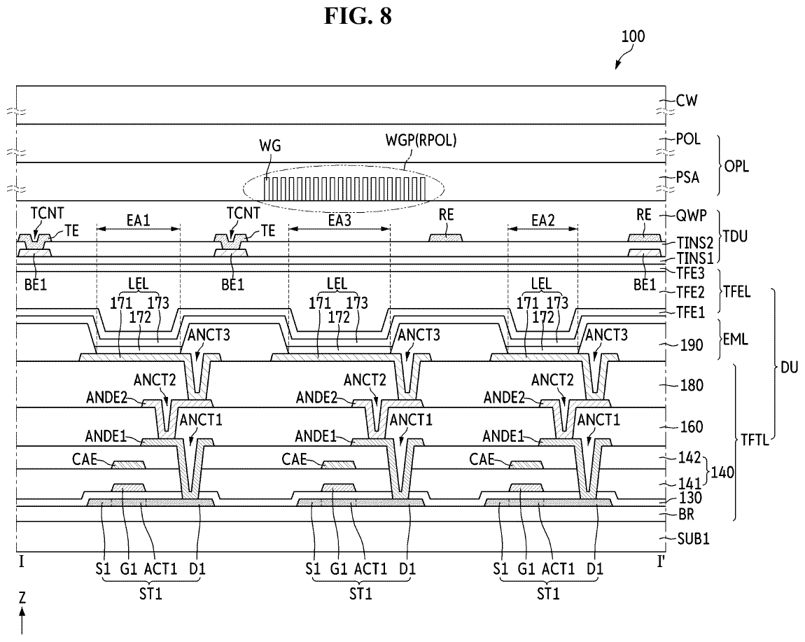

FIG. 8 is an embodiment in which the third touch insulating layer TINS3 of FIG. 6 is replaced with a phase retardation layer QWP.

Referring to FIG. 8, the phase retardation layer QWP, instead of the third touch insulating layer TIN3, may be located on a second touch insulating layer TINS2 and sensor electrodes SE. A reflective polarizing member RPOL may be located on the phase retardation layer QWP. That is, the phase retardation layer QWP may be located between the second touch insulating layer TINS2 and the reflective polarizing member RPOL.

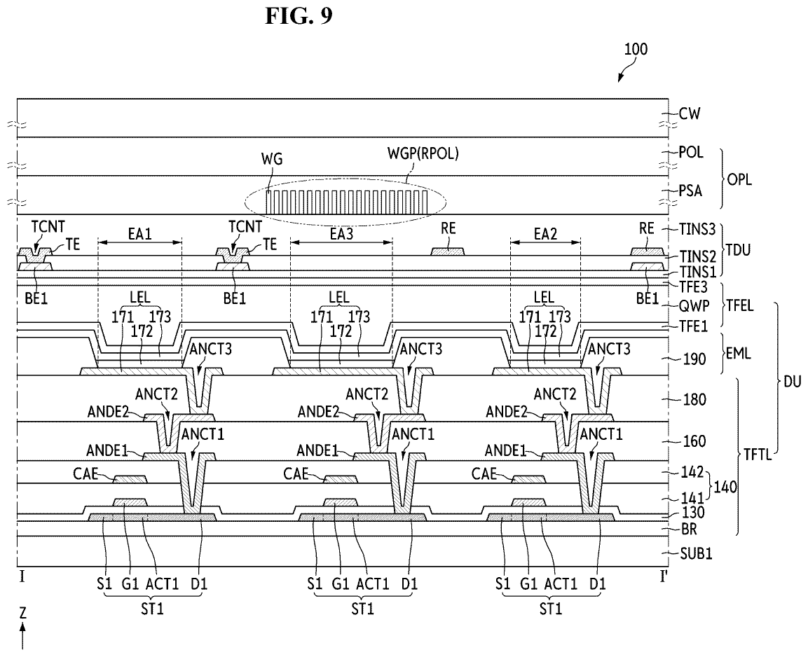

FIG. 9 is an embodiment in which the encapsulating organic layer TFE2 of FIG. 6 is replaced with a phase retardation layer QWP.

Referring to FIG. 9, the phase retardation layer QWP, instead of the encapsulating organic layer TFE2, may be located on a first encapsulating inorganic layer TFEL. A second encapsulating inorganic layer TFE3 may be located on the phase retardation layer QWP. In addition, a reflective polarizing member RPOL may be located on a third touch insulating layer TINS3.

That is, the phase retardation layer QWP is a layer which replaces the encapsulating organic layer TFE2 illustrated in FIG. 6. A base member, an alignment layer, or a liquid crystal layer of the phase retardation layer QWP may be formed to have a thickness of about 5 μm to about 10 μm. Accordingly, light emitting layers 172 can be protected from foreign substances such as dust.

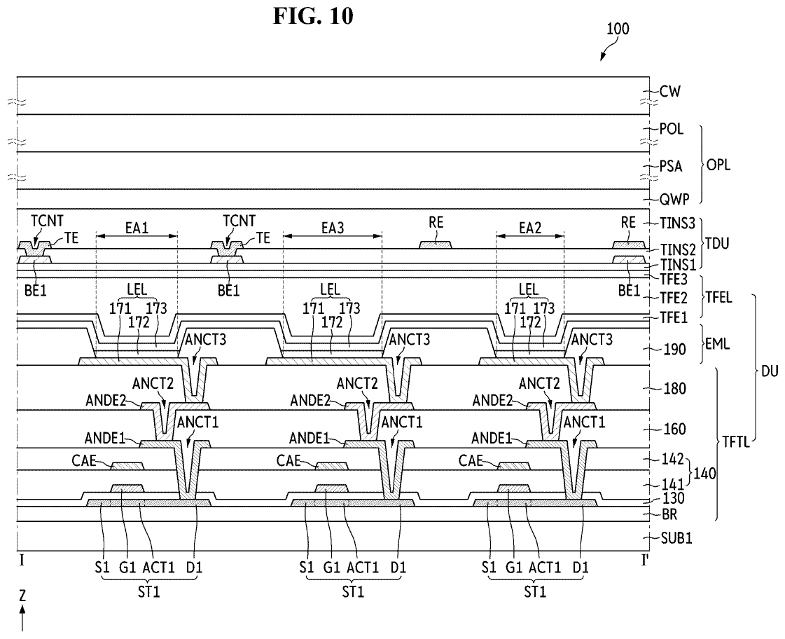

FIG. 10 is Comparative Example 1 in which a reflective polarizing member RPOL is completely removed from the embodiment of FIG. 6, and a phase retardation layer QWP and an absorptive polarizing member POL are applied.

Referring to FIG. 10, the phase retardation layer QWP may be located on a third touch insulating layer TINS3, and the absorptive polarizing member POL may be located on the phase retardation layer QWP. An adhesive layer PSA may be located between the phase retardation layer QWP and the absorptive polarizing member POL to bond the phase retardation layer QWP and the POL together.

Since the transmittance of the absorptive polarizing member POL is 50% or less, the absorptive polarizing member POL may block a portion of light emitted by light emitting elements LEL. Therefore, the light efficiency of the light emitting elements LEL may be reduced.

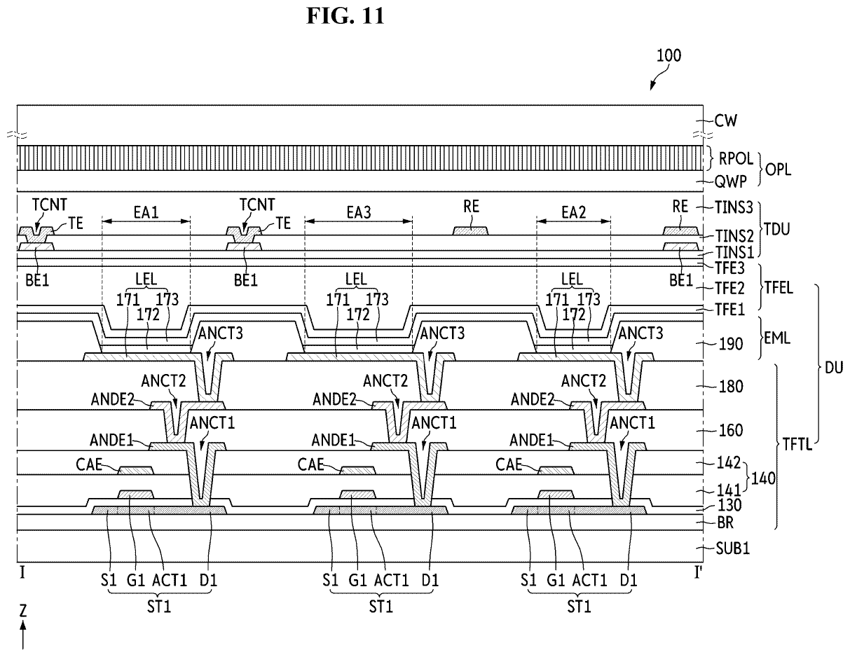

FIG. 11 is Comparative Example 2 in which an absorptive polarizing member POL is completely removed from the embodiment of FIG. 6, and a phase retardation layer QWP and a reflective polarizing member RPOL are applied across all emission areas.

Referring to FIG. 11, the phase retardation layer QWP may be located on a third touch insulating layer TINS3, and the reflective polarizing member RPOL may be directly located on the phase retardation layer QWP. The reflective polarizing member RPOL of FIG. 11 is different from the embodiment of FIG. 6 in that it overlaps a first emission portion EA1, a second emission portion EA2, and a third emission portion EA3.

The reflective polarizing member RPOL may reflect a portion of light emitted by light emitting elements LEL, and the reflected light may be recycled. Therefore, the light efficiency of the light emitting elements LEL may be increased. When the light efficiency of the light emitting element LEL is increased, the lifespan of the light emitting elements LEL may be extended. A light emitting element LEL of the third emission portion EA3, which emits blue light, has a shorter lifespan than light emitting elements LEL of the first emission portion EA1 and the second emission portion EA2. Therefore, the application of the reflective polarizing member RPOL can solve the lifespan problem of the blue light emitting element. However, since the reflective polarizing member RPOL also reflects light incident from the outside, if the reflective polarizing member RPOL is placed on the first through third emission portions EA1 through EA3, reflectivity due to the external light may be high, which may cause a decrease in visibility.

TABLE 1

| | Light Efficiency | | | | |
|---|---|---|---|---|---|
| | W | R | G | B | Reflectivity |
| Embodiment 1 | 115% | 100% | 100% | 130% | 4.71% |
| Comparative | 100% | 100% | 100% | 100% | 4.62% |
| example 1 | | | | | |
| Comparative | 134% | 135% | 134% | 130% | 39.2% |
| example 2 | | | | | |

Referring to FIGS. 6, 10 and 11 and Table 1, light efficiency is based on the light luminance of the light emitting elements LEL in Comparative Example 1 being 100%. The higher the light efficiency (percent, %), the higher the light luminance of the light emitting elements LEL under the same conditions. ‘W’ represents white light efficiency, ‘R’ represents red light efficiency, ‘G’ represents green light efficiency, and ‘B’ represents blue light efficiency.

Reflectivity (percent, %) refers to the ratio of light which is reflected to light incident on the display panel 100 from the outside thereof.

Embodiment 1 includes the reflective polarizing member RPOL as illustrated in FIG. 6. Therefore, the embodiment of the present specification can increase the blue light efficiency B and the white light efficiency W while maintaining the reflectivity almost similar to that of Comparative Example 1. On the other hand, Comparative Example 2 can increase the light efficiency compared with Comparative Example 1, but increases the reflectivity significantly.

That is, one or more embodiment of the present specification which includes the reflective polarizing member RPOL has the advantage of preventing a decrease in the visibility of a displayed image while increasing the light efficiency of the light emitting elements LEL, compared with Comparative Example 1 and Comparative Example 2.

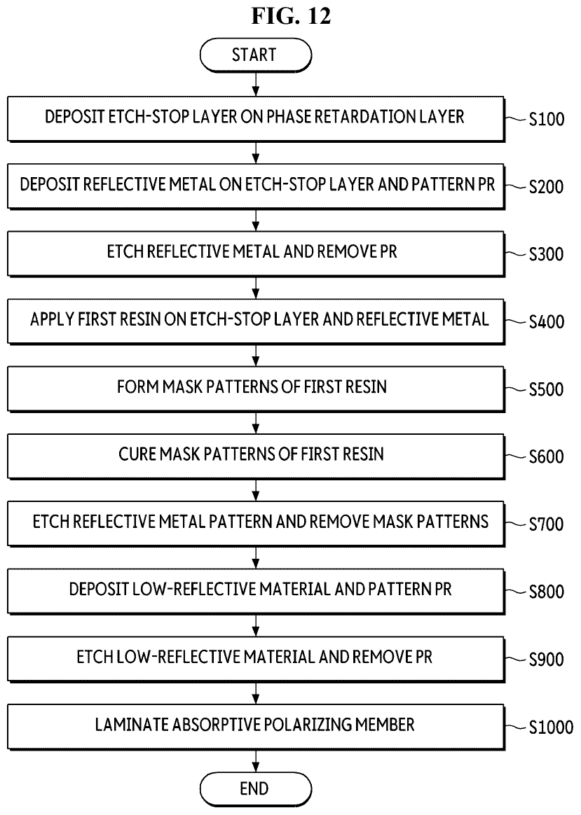

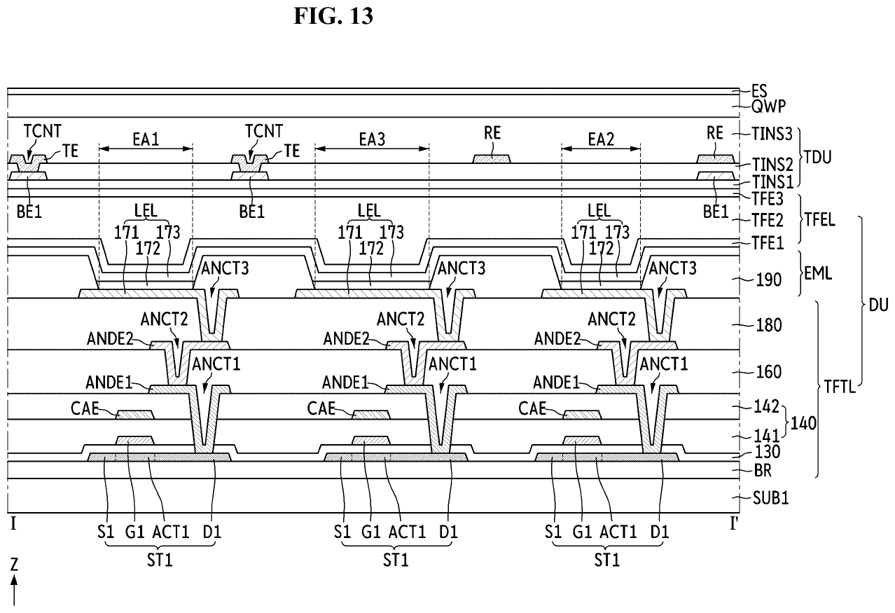

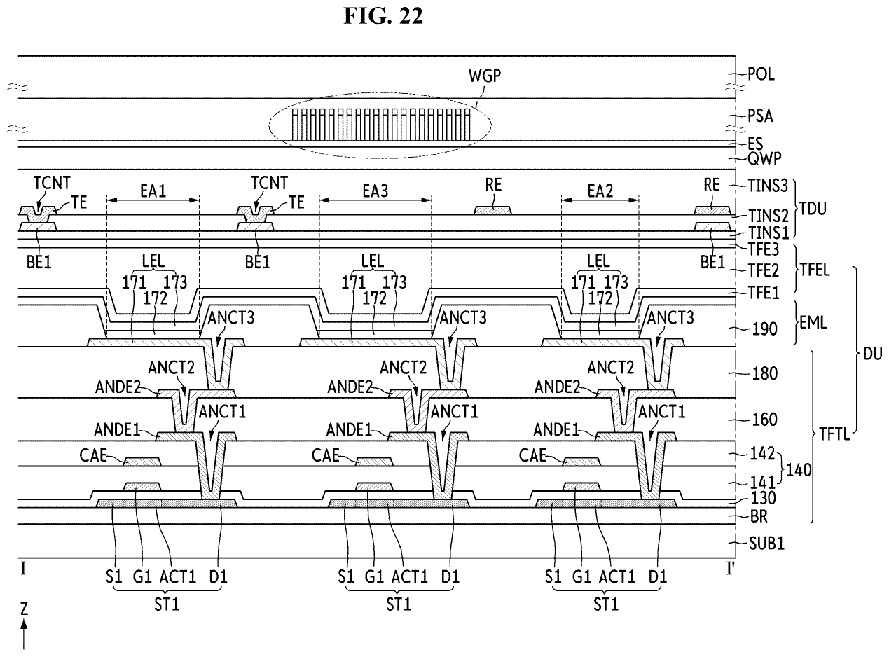

FIG. 12 is a flowchart illustrating a process of manufacturing (or providing) a display device 10 according to an embodiment. FIGS. 13 through 22 are cross-sectional views illustrating processes of manufacturing (or providing) the display device 10 according to the flowchart of FIG. 12.

A stacked structure inclusive of the substrate SUB and the respective layer on which the reflective polarizing member RPOL is formed, is provided. For example, the phase retardation layer QWP of the stacked structure provides a base layer on which the reflective polarizing member RPOL is formed.

First, an etch-stop layer ES is formed on a phase retardation layer QWP as a base layer (operation S100 of FIG. 12).

Referring to FIG. 13, the etch-stop layer ES may be deposited on the entire surface of the phase retardation layer QWP to prevent damage to the phase retardation layer QWP during the manufacturing process. The etch-stop layer ES may include silicon oxide (SiOₓ) or silicon oxynitride (SiON).

Second, a reflective metal ML is deposited on the etch-stop layer ES, and a photoresist PR is patterned (operation S200 of FIG. 12).

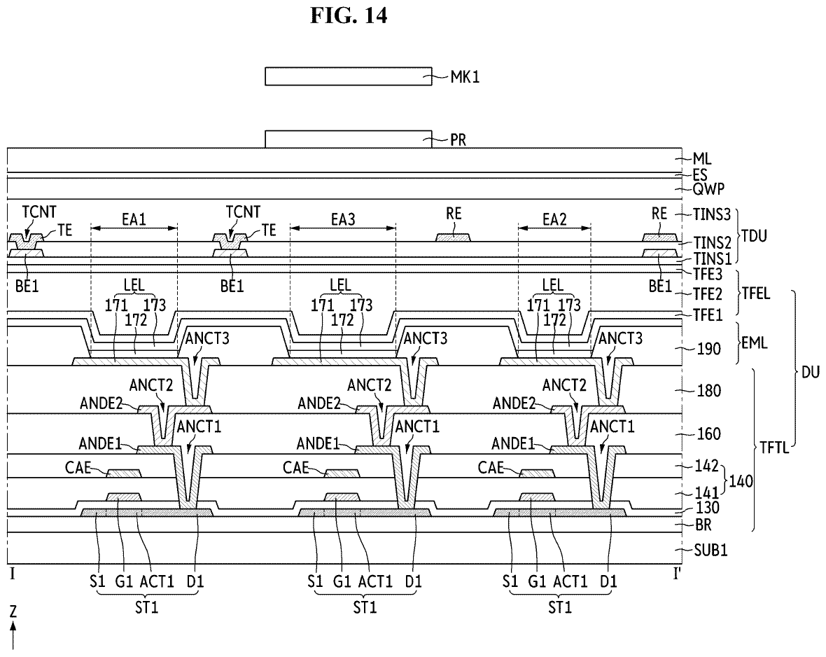

Referring to FIG. 14, the reflective metal ML is deposited on the etch-stop layer ES. The reflective metal ML may be provided on an entirety of the etch-stop layer ES, as a preliminary reflective metal layer. The reflective metal ML may be one or more metals selected from aluminum (Al), chromium (Cr), gold (Au), silver (Ag), copper (Cu), nickel (Ni), iron (Fe), tungsten (W), cobalt (Co), titanium (Ti) and molybdenum (Mo), an alloy thereof, or an oxide or nitride thereof. The photoresist PR is applied on the deposited reflective metal ML and then exposed and developed by placing a first mask MK1 to overlap a third emission portion EA3 so that a reflective metal pattern can be formed in the third emission portion EA3. The photoresist PR patterned by the exposure and development may remain in an area overlapping the first mask MK1 and may be removed from other or remaining areas. The photoresist PR patterned by the exposure and development may overlap the third emission portion EA3 in the thickness direction.

Third, the preliminary layer of the reflective metal ML is etched, and the photoresist PR is removed (operation S300 of FIG. 12).

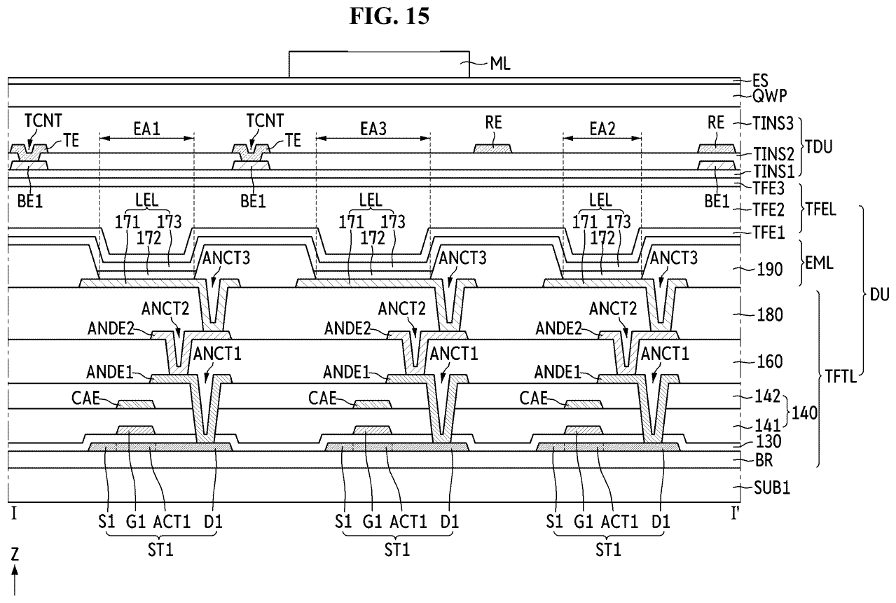

Referring to FIG. 15, the reflective metal ML may be etched by a dry etching process. A portion of the reflective metal ML which is not overlapped by the photoresist PR is etched, and a portion of the reflective metal ML which is overlapped by the photoresist PR remains as a reflective metal pattern. When the photoresist PR on the reflective metal ML is removed, the reflective metal ML which overlaps the third emission portion EA3 may be formed. A remaining area of the etch-stop layer ES may be exposed to outside the reflective metal ML

Fourth, a first resin R1 is applied on the etch-stop layer ES and the reflective metal ML (operation S400 of FIG. 12).

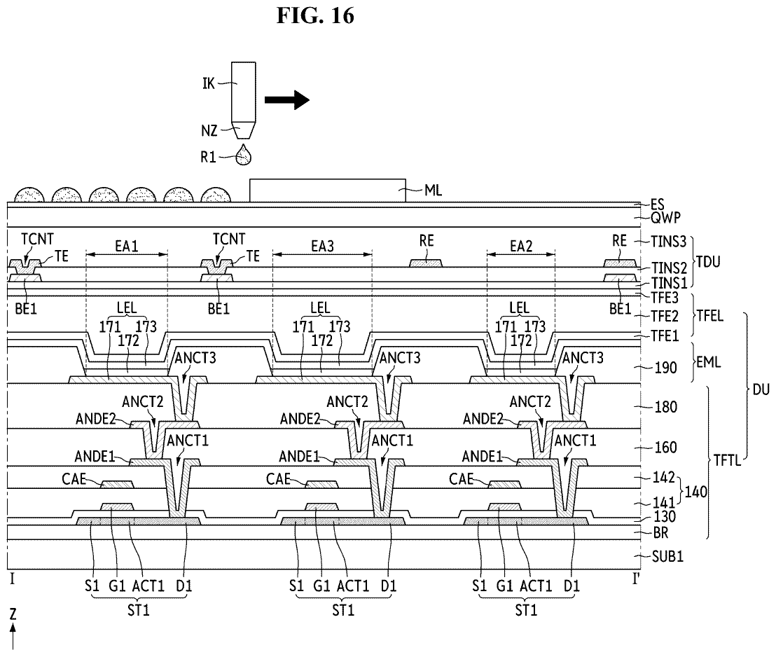

Referring to FIG. 16, an inkjet device IK may spray the first resin R1 through a nozzle NZ while moving in a direction (refer to arrow in FIG. 16), for example, an eighth direction. The first resin R1 may be evenly applied on the etch-stop layer ES and the reflective metal ML. The eighth direction may be substantially the same direction as any one of the first direction, the second direction, the fourth direction DR4, and the fifth direction DR5. Alternatively, the eighth direction may be a direction defined in a plane defined by the first direction and the second direction and may be a direction different from the first direction, the second direction, the fourth direction DR4 and the fifth direction DR5.

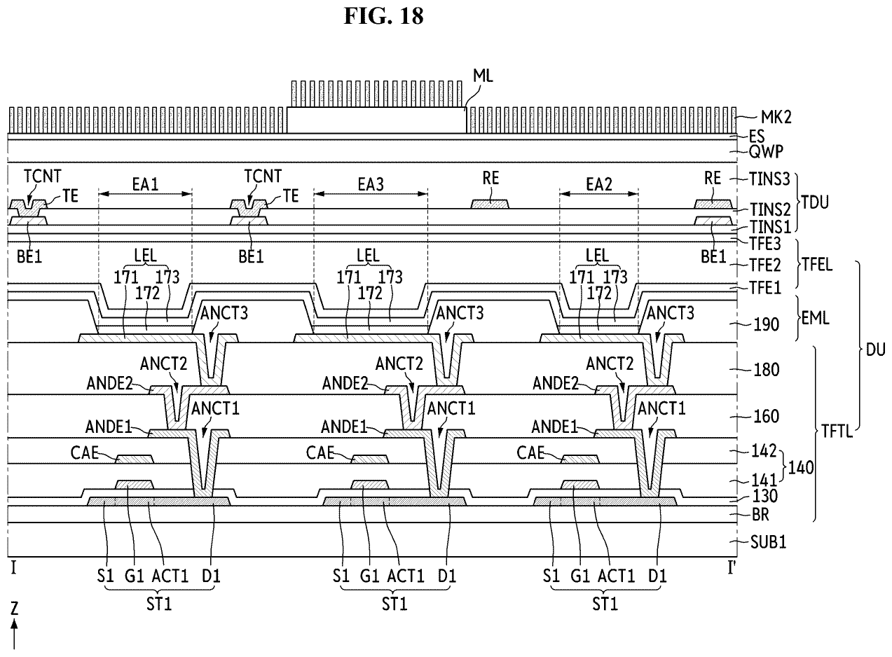

Fifth, second mask patterns MK2 formed from the first resin R1 (see FIG. 18) are formed on the etch-stop layer ES and the reflective metal ML using an imprint mold MD (operation S500 of FIG. 12).

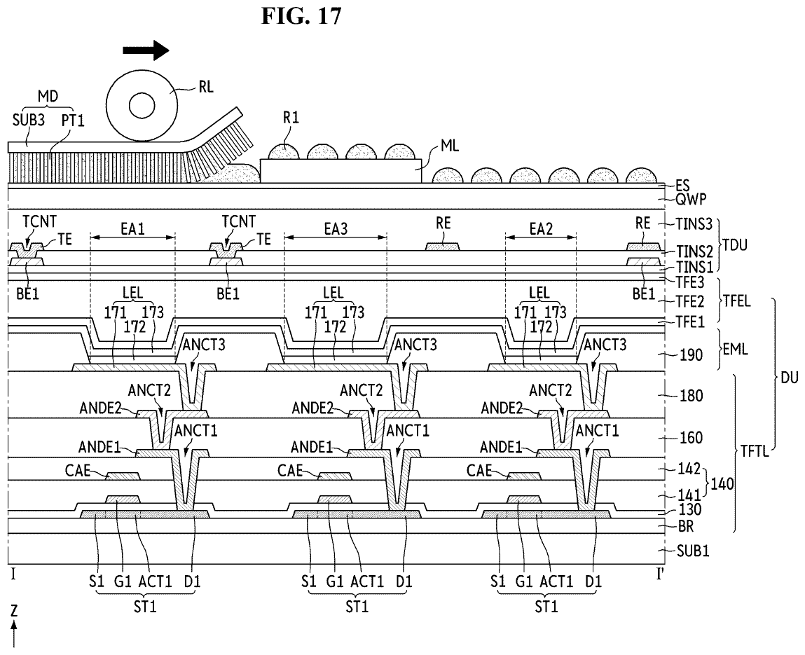

Referring to FIG. 17, the imprint mold MD is placed on the layer of the first resin R1. Then, the imprint mold MD is pressed by moving a roller RL in a direction, for example, the eighth direction or a ninth direction, along the layer of the first resin R1. Accordingly, the second mask patterns MK2 (see FIG. 18) may be formed. The imprint mold MD may include protruding patterns PT1 which are identical to the shape, dimension, location, etc. of wire grid patterns WGP. The imprint mold MD may include protruding patterns PT1 having a width of about 130 μm or less in order to give polarization to a visible light region having a wavelength of about 380 nm to about 780 nm. The protruding patterns PT1 may have a width and spacing of about 45 nm. The widths and spacing may be defined in a direction along the plane (e.g., a planar direction)/

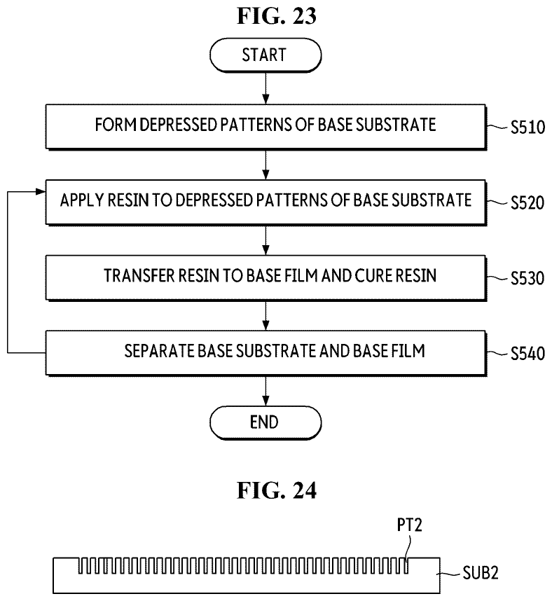

A process for forming (or providing) the imprint mold MD will be described later with reference to FIGS. 23 through 27.

Sixth, the first resin R1 formed into the second mask patterns MK2 is cured (operation S600 of FIG. 12). The second mask patterns MK2 may be defined across all emission areas.

The first resin R1 formed into the second mask patterns MK2 is a photocurable resin and may be cured by irradiating ultraviolet light.

Seventh, the reflective metal ML is etched, and the second mask patterns MK2 are removed (operation S700 of FIG. 12).

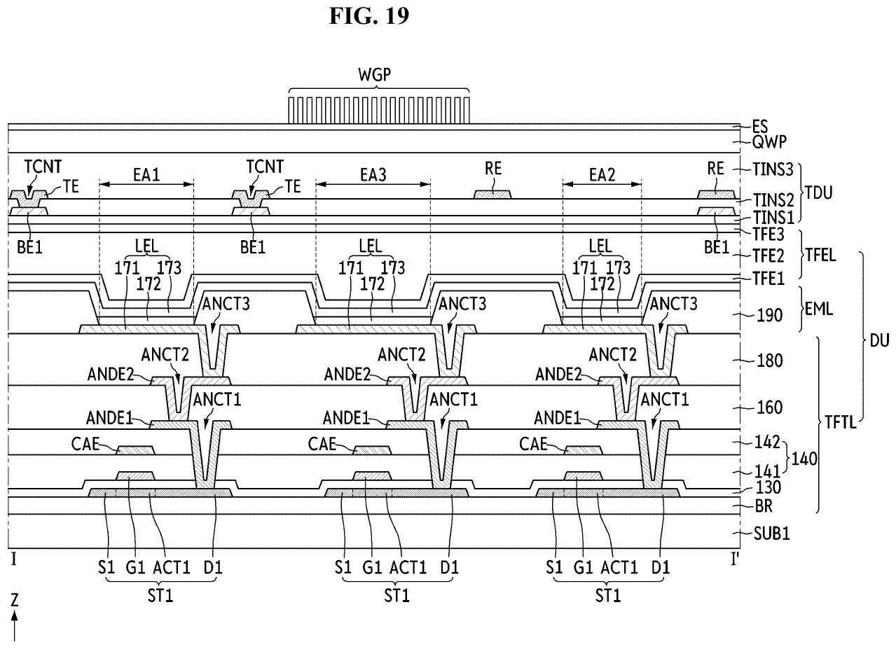

Referring to FIG. 18, material of the reflective metal ML in portions where the second mask patterns MK2 are located is not etched by being protected by the second mask pattern MK2. On the other hand, the material of the reflective metal ML in portions where the second mask patterns MK2 are not located is etched. When the second mask patterns MK2 are removed, the reflective metal ML may be formed into wire grid patterns WGP as illustrated in FIG. 19.

Eighth, a low-reflective material LR is deposited on the etch-stop layer ES and the wire grid patterns WGP, and a photoresist PR is patterned (operation S800 of FIG. 12).

The low-reflective material LR may be a material including molybdenum tantalum oxide (MTO). The low-reflective material LR is intended to reduce the reflection of the wire grid patterns WGP made of the reflective metal ML.

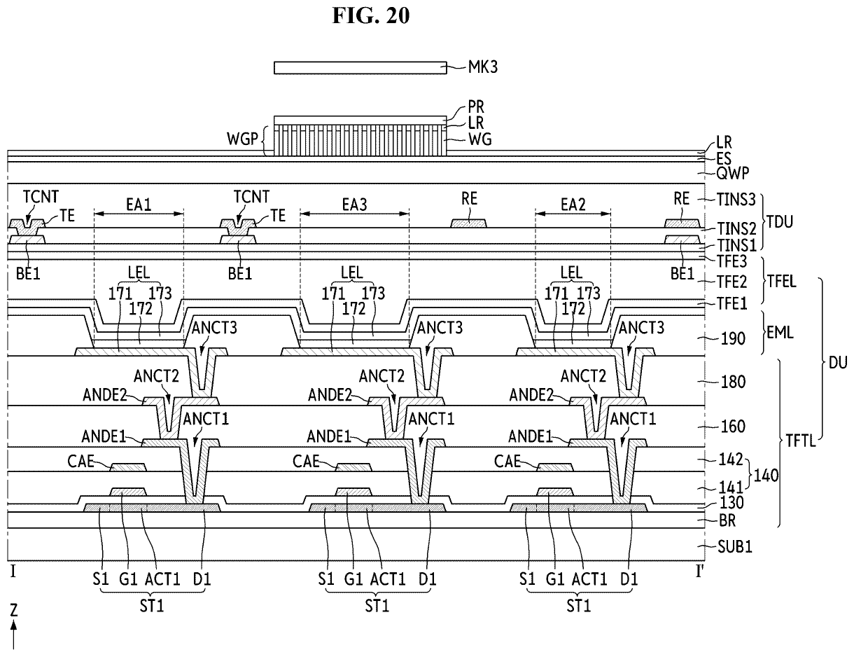

Referring to FIG. 20, the low-reflective material LR may be deposited on the entire surface including the etch-stop layer ES and the wire grid patterns WGP. Since a gap between wire grids WG is very small, the low-reflective material LR may not be deposited between the wire grids WG, but may be deposited only on each wire grid WG.

The photoresist PR is applied on the deposited low-reflective material LR and then exposed and developed by placing a third mask MK3 to overlap the third emission portion EA3 so that a reflective metal pattern can be formed in the third emission portion EA3. The photoresist PR, which has undergone the exposure and development process, may remain in a portion overlapping the third mask MK3 and may be removed from other portions. The photoresist PR, which has undergone the exposure and development process, may overlap the third emission portion EA3 in the thickness direction.

Ninth, the low-reflective material LR is etched, and the photoresist PR is removed (operation S900 of FIG. 12).

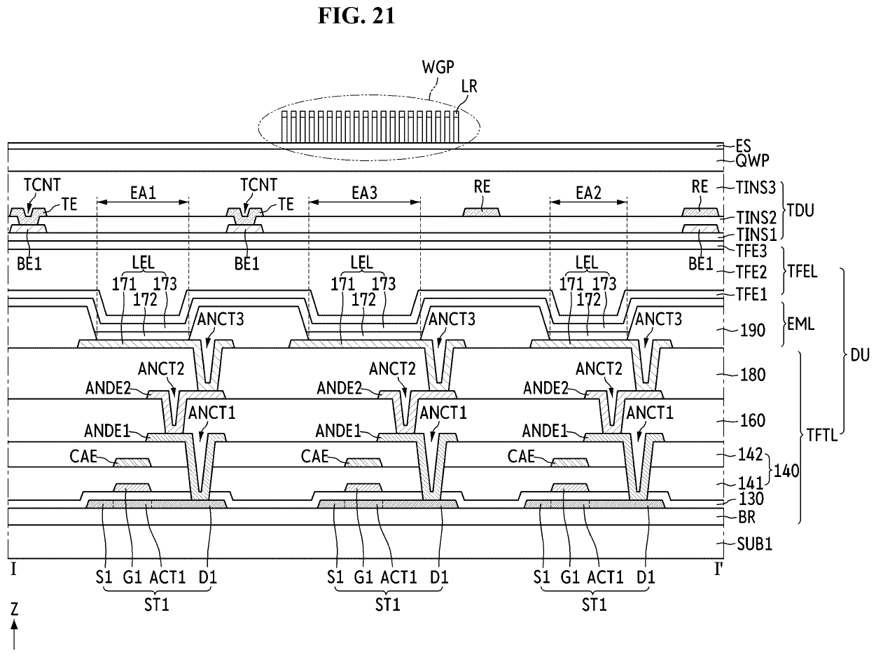

Referring to FIG. 21, the low-reflective material LR not covered by the photoresist pattern PR may be etched by a dry etching process.

Tenth, an absorptive polarizing member POL is laminated on the wire grid patterns WGP (operation S1000 of FIG. 12).

The absorptive polarizing member POL may be attached to the wire grid patterns WGP and the phase retardation layer QWP by an adhesive layer PSA. Since the wire grid patterns WGP are tens of nanometers thick, they may be covered by the adhesive layer PSA having a thickness of tens of micrometers.

FIG. 23 is a flowchart illustrating a process of manufacturing (or providing) the imprint mold MD shown in FIG. 17. FIGS. 24 through 27 are cross-sectional views illustrating processes of manufacturing (or providing) the imprint mold MD according to the flowchart of FIG. 23.

A large-area imprint mold MD having precise patterns is used to manufacture the wire grid patterns WGP illustrated in FIG. 6. A method of manufacturing an imprint mold MD will now be described in detail with reference to FIGS. 23 through 27.

First, depressed patterns PT2 are formed in a base substrate SUB2 (operation S510 of FIG. 23).

FIG. 24 is a cross-sectional view illustrating the depressed patterns PT2 formed in the base substrate SUB2 to have the same width and spacing as wire grid patterns WGP. For example, each depressed pattern PT2 of the base substrate SUB2 may have a width of about 45 μm, and the depressed patterns PT2 may be arranged at intervals of about 45 nm. To form precise patterns, the base substrate SUB2 may be a silicon wafer.

After a photoresist (not shown) is applied on the base substrate SUB2, a mask, which includes patterns having the same width and spacing as the wire grid patterns WGP, is placed on the photoresist PR. Then, the photoresist PR is exposed and developed.

The photoresist PR may be removed from areas exposed to light by the mask patterns and may remain in other areas. In a subsequent etching process, the base substrate SUB2 in portions where the photoresist remains is not etched, and the base substrate SUB2 in portions where the photoresist is removed is etched. The etched base substrate SUB2 may have the depressed patterns PT2 as illustrated in FIG. 24.

Second, a second resin R2 is applied to the depressed patterns PT2 of the base substrate SUB2 (operation S520 of FIG. 23).

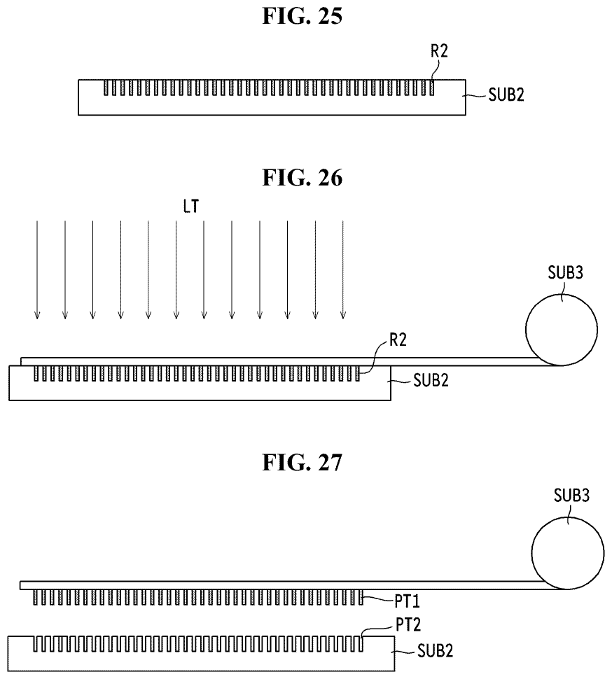

Referring to FIG. 25, the depressed patterns PT2 of the base substrate SUB2 may be filled with the second resin R2.

Third, a base film SUB3 of the imprint mold MD is placed on the engraved patterns PT2 of the base substrate SUB2 which are filled with the second resin R2, and the second resin R2 is photocured (operation S530 of FIG. 23).

Referring to FIG. 26, the base film SUB3 may be a PET film. The base film SUB3 is placed on the depressed patterns PT2 of the base substrate SUB2 which are filled with the second resin R2, and the second resin R2 is cured by irradiating light LT to the second resin R2. Accordingly, the second resin R2 and the base film SUB3 may have selected adhesion between them. Here, the light LT irradiated to the second resin R2 may be light having a wavelength in an ultraviolet region.

Fourth, the base substrate SUB2 and the base film SUB3 are separated (operation S540 of FIG. 23).

Referring to FIG. 27, the base substrate SUB2 and the base film SUB3 having the second resin R2 attached thereto are separated to form an imprint mold MD including protruding patterns PT1 which protrude from the base film SUB3.

When the base substrate SUB2 is a silicon wafer, the total area of the base substrate SUB2 is smaller than the total area of the display panel 100 or the area of a mother substrate for forming the display panel 100. Therefore, an imprint mold MD applied to a large area corresponding to the area of the display panel 100 or the area of the mother substrate may be provided by repeating operations S520 through S540 of FIG. 23.

In an embodiment, the method includes providing light emitting elements respectively in a first emission area and a second emission area of the display device, providing an encapsulation layer on the light emitting elements, attaching a phase retardation layer onto the encapsulation layer, depositing an etch-stop layer on the phase retardation layer, providing a reflective metal pattern in the second emission area by depositing a reflective metal on the etch-stop layer and patterning the reflective metal, providing a first resin onto the reflective metal pattern using an inkjet device, providing a mask pattern on the reflective metal pattern by pressing a mold having a protruding pattern corresponding to a wire grid pattern of the display device on the first resin by using a roller, and providing the wire grid pattern in the second emission area and excluded from the first emission area, by etching the reflective metal pattern using the mask pattern and removing the mask pattern.

The method may further include depositing a low-reflective material on the wire grid pattern, providing a photoresist pattern which overlaps the wire grid pattern in a thickness direction of the substrate, on the low-reflective material, providing a low-reflective layer on the wire grid pattern by etching a portion of the low-reflective material which is exposed outside the photoresist pattern without being covered by the photoresist pattern and attaching an absorptive polarizing member on the wire grid pattern having the low-reflective layer thereon.

The providing of the mold having the protruding pattern corresponding to the wire grid pattern includes providing depressed patterns corresponding to the wire grid pattern, in a base substrate, applying a second resin to fill the depressed patterns, providing a base film of the mold on the base substrate having the second resin in the depressed patterns, curing the second resin on the base substrate with the base film on the base substrate by irradiating ultraviolet light to the second resin through the base film, and separating the base substrate from the base film having cured second resin as the protruding pattern of the mold which is on the base film.

A display device 10 according to an embodiment can be applied to various electronic devices. An electronic device 100 according to an embodiment includes the display device 10 described above and may further include modules or devices having other additional functions, in addition to the display device 10.

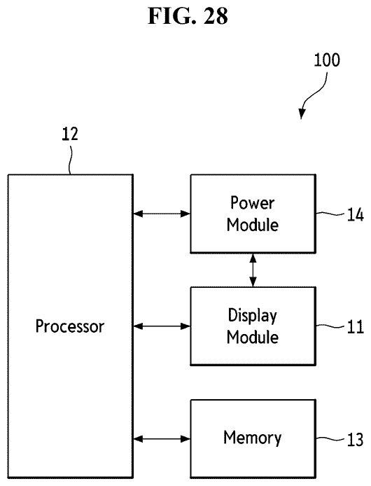

FIG. 28 is a block diagram of an electronic device 100 according to an embodiment. Referring to FIG. 28, the electronic device 100 according to the embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter or a battery device, and a power conversion module which generates power necessary for the operation of the electronic device 100 by converting power supplied by the power supply module.

At least one of the elements of the electronic device 100 described above may be included in the display device 10 according to the above-described embodiments. In addition, some of individual modules functionally included in one module may be included in the display device 10, and other modules may be provided separately from the display device 10. For example, the display device may include the display module 11, and the processor 12, the memory 13 and the power module 14 may be provided not in the display device 10, but in the form of other devices within the electronic device 100.

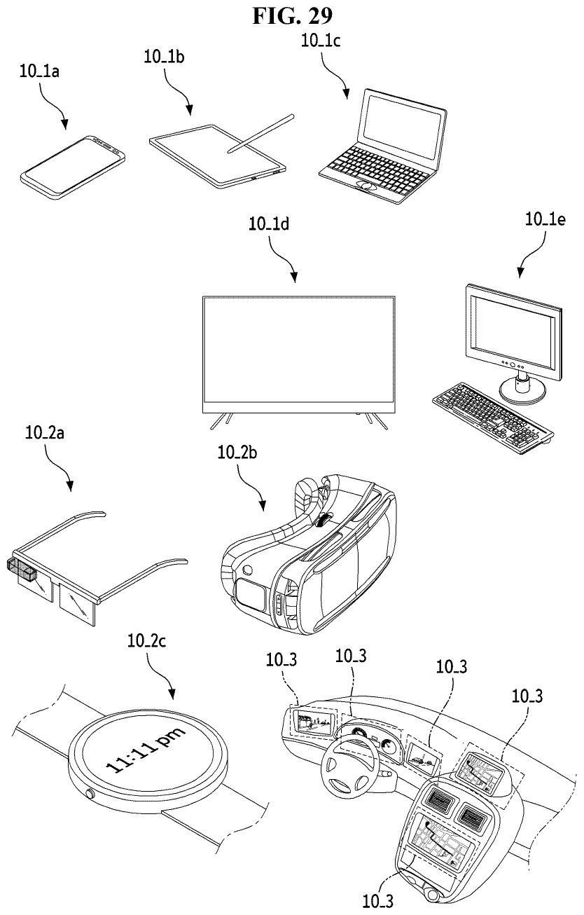

FIG. 29 is a schematic diagram of electronic devices according to various embodiments.

Referring to FIG. 29, various electronic devices to which a display device 10 according to embodiments is applied may include not only image display electronic devices, such as a smartphone 10_1a, a tablet PC 10_1b, a laptop 10_1c, a television 10_1d and a desk monitor 10_1e, but also wearable electronic devices including a display module, such as smart glasses 10_2a, a head-mounted display 10_2b and a smart watch 10_2c, and vehicle electronic devices 10_3 including a display module, such as a center information display (CID) and a room mirror display placed on an instrument panel, a center fascia and a dashboard of a vehicle.

In an embodiment, the display device includes emission areas including light emitting elements emitting lights in different wavelength bands from each other, respectively, an encapsulation layer on the light emitting elements, a reflective polarizing member on the encapsulation layer and including a wire grid pattern which, among incident light from outside the display device, transmits light having an optical axis in a first direction and reflects light having an optical axis in a second direction orthogonal to the first direction, and an absorptive polarizing member which is on the reflective polarizing member and transmits the light having the optical axis in the first direction together with absorbing the light having the optical axis in the second direction. The wire grid pattern overlaps an emission area among the emission areas and non-overlaps remaining emission areas.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
emission areas including light emitting elements, respectively;
an encapsulation layer on the light emitting elements;
a reflective polarizing member on the encapsulation layer and comprising a wire grid pattern which, among incident light from outside the display device, transmits light having an optical axis in a first direction and reflects light having an optical axis in a second direction orthogonal to the first direction; and
an absorptive polarizing member which is on the reflective polarizing member and transmits the light having the optical axis in the first direction together with absorbing the light having the optical axis in the second direction.

2. The display device of claim 1, wherein among the light emitting elements and the emission areas:
a first light emitting element is in a first emission area and emits light of a first wavelength band;
a second light emitting element is in a second emission area and emits light of a second wavelength band; and
a third light emitting element is in a third emission area and emits light of a third wavelength band.

3. The display device of claim 2, wherein the wire grid pattern overlaps the third emission area and non-overlaps the first emission area and the second emission area.

4. The display device of claim 3, wherein the light of the third wavelength band is light of a blue wavelength band.

5. The display device of claim 2, wherein the absorptive polarizing member overlaps the first emission area, the second emission area and the third emission area.

6. The display device of claim 1, further comprising an adhesive layer which is between the reflective polarizing member and the absorptive polarizing member.

7. The display device of claim 6, wherein the adhesive layer covers the wire grid pattern.

8. The display device of claim 1, further comprising a phase retardation layer which delays a phase of the incident light.

9. The display device of claim 8, wherein the phase retardation layer comprises:
an alignment layer on the encapsulation layer; and
a liquid crystal layer comprising liquid crystals on the alignment layer.

10. The display device of claim 9, further comprising a touch sensing layer on the encapsulation layer,
wherein the touch sensing layer comprises sensor electrodes which are connected to each other by a connector located in a different layer from the sensor electrodes.

11. The display device of claim 10, wherein
the touch sensing layer further comprises a first touch insulating layer,
the phase retardation layer is between the sensor electrodes and the reflective polarizing member, respectively, and
the first touch insulating layer is between the sensor electrodes and the phase retardation layer, respectively.

12. The display device of claim 10, wherein
the touch sensing layer further comprises a first touch insulating layer,
the phase retardation layer is between the connector and the sensor electrodes, respectively, and
the first touch insulating layer is between the sensor electrodes and the reflective polarizing member, respectively.

13. The display device of claim 10, wherein
the touch sensing layer further comprises a first touch insulating layer between the sensor electrodes and the connector, respectively, and
the phase retardation layer is between the first touch insulating layer and the reflective polarizing member.

14. The display device of claim 10, wherein the encapsulation layer comprises:
a first encapsulating inorganic layer on the light emitting elements;
a phase retardation layer on the first encapsulating inorganic layer; and
a second encapsulating inorganic layer on the phase retardation layer.

15. A method of providing a display device, the method comprising:
providing light emitting elements respectively in a first emission area and a second emission area of the display device,
providing an encapsulation layer on the light emitting elements,
attaching a phase retardation layer onto the encapsulation layer;
depositing an etch-stop layer on the phase retardation layer;
providing a reflective metal pattern in the second emission area by depositing a reflective metal on the etch-stop layer and patterning the reflective metal;
providing a first resin onto the reflective metal pattern using an inkjet device;
providing a mask pattern on the reflective metal pattern by pressing a mold having a protruding pattern corresponding to a wire grid pattern of the display device on the first resin by using a roller; and
providing the wire grid pattern in the second emission area and excluded from the first emission area, by etching the reflective metal pattern using the mask pattern and removing the mask pattern.

16. The method of claim 15, further comprising:
depositing a low-reflective material on the wire grid pattern;
providing a photoresist pattern which overlaps the wire grid pattern in a thickness direction of the substrate, on the low-reflective material;
providing a low-reflective layer on the wire grid pattern by etching a portion of the low-reflective material which is exposed outside the photoresist pattern without being covered by the photoresist pattern; and
attaching an absorptive polarizing member on the wire grid pattern having the low-reflective layer thereon.

17. The method of claim 15, wherein the providing of the mold having the protruding pattern corresponding to the wire grid pattern comprises:
providing depressed patterns corresponding to the wire grid pattern, in a base substrate;
applying a second resin to fill the depressed patterns;
providing a base film of the mold on the base substrate having the second resin in the depressed patterns;
curing the second resin on the base substrate with the base film on the base substrate by irradiating ultraviolet light to the second resin through the base film; and
separating the base substrate from the base film having cured second resin as the protruding pattern of the mold which is on the base film.

18. An electronic device comprising:
a display module displaying an image; and
a processor transmitting an image data signal to the display module,
wherein the display module comprises:
emission areas including light emitting elements emitting lights in different wavelength bands from each other, respectively;
an encapsulation layer on the light emitting elements;
a reflective polarizing member on the encapsulation layer and comprising a wire grid pattern which, among incident light from outside the display device, transmits light having an optical axis in a first direction and reflects light having an optical axis in a second direction orthogonal to the first direction; and
an absorptive polarizing member which is on the reflective polarizing member and transmits the light having the optical axis in the first direction together with absorbing the light having the optical axis in the second direction,
wherein the wire grid pattern overlaps an emission area among the emission areas and non-overlaps remaining emission areas.

19. The electronic device of claim 18, wherein light emitted from the emission area which is overlapped by the wire grid pattern is light of a blue wavelength band.

20. The electronic device of claim 18, wherein light emitted from the remaining emission areas which is non-overlapped by the wire grid pattern includes lights of a red wavelength band and a green wavelength band.
